(19) United States
(12) Patent Application Publication
(10) Pub. No.: US 2025/0241123 A1
(43) Pub. Date: Jul. 24, 2025

(54) DISPLAY DEVICE

(71) Applicant: Samsung Display Co., LTD., Yongin-si (KR)

(72) Inventors: Seul Ong KIM, Yongin-si (KR); Eun Gyoung PARK, Yongin-si (KR); Heung Su PARK, Yongin-si (KR); Hui Ju PARK, Yongin-si (KR); Jae Hoon HWANG, Yongin-si (KR)

(21) Appl. No.: 18/817,883

(22) Filed: Aug. 28, 2024

(30) Foreign Application Priority Data
Jan. 23, 2024 (KR) 10-2024-0010334

(51) Int. Cl. H10K 50/19; H10K 59/38; H10K 59/80; H10K 102/00

(52) U.S. Cl. CPC H10K 50/19; H10K 59/38; H10K 59/80518; H10K 59/877; H10K 2102/331; H10K 2102/351

(57) ABSTRACT

A display device includes a first substrate including a first emission area and a second emission area spaced apart from each other; a first light emitting element on the first substrate and overlapping the first emission area and a second light emitting element on the first substrate and overlapping the second emission area; a light transmitting layer on the first light emitting element; and a first wavelength conversion layer on the second light emitting element and including a light scatterer, wherein each of the first light emitting element and the second light emitting element includes four or more stacks, at least two of (e.g., selected from among) the stacks emit first component light, at least two of the stacks emit second component light, and any two adjacent stacks of the stacks emit the first component light, and other two adjacent stacks of the stacks emit the second component light.

### CROSS-REFERENCE TO RELATED APPLICATION

The present application claims priority to and the benefit of Korean Patent Application No. 10-2024-0010334, filed on Jan. 23, 2024, in the Korean Intellectual Property Office, the entire content of which is herein incorporated by reference.

### BACKGROUND

### 1. Field

Embodiments of the present disclosure described herein are related to a display device.

### 2. Description of the Related Art

The importance of display devices has increased with the development of multimedia. Accordingly, one or more suitable display devices, such as liquid crystal display devices (LCDs) and/or organic light emitting diode display devices (OLEDs), have been developed.

Among these display devices, a self-light emitting display device includes self-light emitting elements, for example, organic light emitting elements. The self-light emitting element may include two electrodes opposing each other and a light emitting layer interposed between the two electrodes. When the self-light emitting element is an organic light emitting element, electrons and holes provided from the two electrodes are combined with each other in the light emitting layer to generate excitons, and light may be emitted (e.g., display images) while the generated excitons change (e.g., relax) from an excited state to a ground state (to, e.g., display an images).

The display device may include color conversion elements implementing colors by receiving light from the organic light emitting elements and/or the like. For example, the color conversion elements may allow an image having one or more suitable colors to be viewed by receiving blue light from the organic light emitting elements and emitting blue, green, and red light, respectively. The color conversion elements may be arranged in the form of a separate substrate on the display device or formed to be directly integrated with elements within the display device.

### SUMMARY

Aspects according to one or more embodiments of the present disclosure are directed toward a display device in which a white angle difference (WAD) depending on a viewing angle of a user is reduced and light efficiency is high.

Aspects according to one or more embodiments of the present disclosure are directed toward a display device in which light efficiency may be high and a white angle difference (WAD) depending on a viewing angle may be small.

However, aspects of the present disclosure are not restricted to those set forth herein. The above and other aspects of the present disclosure will become more apparent to one of ordinary skill in the art to which the present disclosure pertains by referencing the detailed description of the present disclosure given herein.

According to one or more embodiments of the present disclosure, a display device includes a first substrate including a first emission area and a second emission area that are spaced and/or apart (e.g., spaced apart or separated) from each other; a first light emitting element arranged on the first substrate and overlapping the first emission area and a second light emitting element arranged on the first substrate and overlapping the second emission area; a light transmitting layer arranged on the first light emitting element; and a first wavelength conversion layer arranged on the second light emitting element and including a light scatterer, wherein each of the first light emitting element and the second light emitting element includes four or more stacks, at least two of (e.g., selected from among) the stacks are configured to emit first component light, at least two of (e.g., selected from among) the stacks are configured to emit second component light, and any two adjacent stacks of (e.g., selected from among) the stacks are configured to emit the first component light, and other two (e.g., remaining two) adjacent stacks of (e.g., selected from among) the stacks are configured to emit the second component light.

The light transmitting layer may not include (e.g., may exclude any of) the light scatterer or includes the light scatterer in an amount of about 8.5 wt % or less based on a total weight of (100 wt % of) the light transmitting layer.

The first component light may be blue light, and the second component light may be green yellow light, and the first light emitting element and the second light emitting element may be configured to emit white light.

Resonance areas of the first component light and the second component light may overlap each other.

Each of the first light emitting element and the second light emitting element may include an anode electrode, a hole injection layer arranged on the anode electrode, a first stack arranged on the hole injection layer, a second stack arranged on the first stack, a third stack arranged on the second stack, a fourth stack arranged on the third stack, a fifth stack arranged on the fourth stack, an electron injection layer arranged on the fifth stack, and a cathode electrode arranged on the electron injection layer, and two of (e.g., selected from among) the first to fifth stacks may be configured to emit the first component light, and the other three (e.g., remaining three) of (e.g., selected from among) the first to fifth stacks may be configured to emit the second component light.

The two stacks configured to emit the first component light may have different thicknesses from each other, and two of (e.g., selected from among) the three stacks configured to emit the second component light may have different thicknesses from each other.

A sum of the thicknesses of the stacks configured to emit the first component light and a sum of the thicknesses of the stacks configured to emit the second component light may be different from each other.

The second stack and the third stack may be configured to emit the first component light, and the first stack, the fourth stack, and the fifth stack may be configured to emit the second component light.

The first stack and the second stack may be configured to emit the first component light, and the third stack, the fourth stack, and the fifth stack may be configured to emit the second component light.

The first to fifth stacks may include (first to fifth) hole transport layers, respectively, and the (first to fifth) hole transport layers have different thicknesses from each other.

Each of the first light emitting element and the second light emitting element may include a first charge generation layer arranged between the first stack and the second stack, a second charge generation layer arranged between the second stack and the third stack, a third charge generation layer arranged between the third stack and the fourth stack, and a fourth charge generation layer arranged between the fourth stack and the fifth stack.

The first wavelength conversion layer further may include a base resin and a first wavelength conversion shifter.

According to one or more embodiments of the present disclosure, a display device includes a first substrate including a first emission area and a second emission area that are spaced and/or apart (e.g., spaced apart or separated) from each other; a plurality of anode electrodes arranged on the first substrate and arranged in the first emission area and the second emission area; a light emitting layer arranged on the anode electrodes and including a plurality of stacks that are sequentially stacked; a cathode electrode arranged on the light emitting layer; a light transmitting layer arranged on the cathode electrode and overlapping the first emission area; and a first wavelength conversion layer arranged on the cathode electrode and overlapping the first emission area, wherein a resonance area of first component light emitted by at least one of (e.g., selected from among) the stacks and a resonance area of second component light emitted by at least another one of (e.g., selected from among) the stacks overlap each other.

The first component light may be blue light, the second component light may be green yellow light, and a fifth resonance area of the first component light and a fourth resonance area of the second component light may overlap each other.

The light emitting layer may include two or more stacks configured to emit the first component light and two or more stacks configured to emit the second component light.

The plurality of anode electrodes may be reflective electrodes.

According to one or more embodiments of the present disclosure, a display device includes a first anode electrode and a second anode electrode arranged spaced and/or apart (e.g., spaced apart or separated) from each other on a first substrate; a light emitting layer arranged on the first anode electrode and the second anode electrode; a cathode electrode arranged on the light emitting layer; a light transmitting layer arranged on the cathode electrode and overlapping the first anode electrode; and a first wavelength conversion layer arranged on the cathode electrode and overlapping the second anode electrode, wherein a thickness of the first anode electrode and a thickness of the second anode electrode are different from each other.

The thickness of the first anode electrode may be smaller than the thickness of the second anode electrode.

The light emitting layer may include a plurality of stacks, and a resonance area of first component light emitted by at least one of (e.g., selected from among) the stacks and a resonance area of second component light emitted by at least another one of (e.g., selected from among) the stacks may overlap each other.

The first component light may be blue light, and the second component light may be green yellow light or green light.

The effects and/or aspects of the present disclosure are not limited to the aforementioned effects, and one or more suitable other effects and/or aspects are included in and/or should be apparent from the present specification.

### BRIEF DESCRIPTION OF THE DRAWINGS

The above and other aspects and features of the present disclosure will become more apparent by describing in more detail embodiments thereof with reference to the attached drawings, in which:

FIG. 1 is a perspective view illustrating a display device according to one or

more embodiments;

FIG. 2 is a schematic cross-sectional view illustrating a cross section taken along the line X1-X1′ of FIG. 1;

FIG. 3 is a plan view of the display device according to one or more embodiments;

FIG. 4 is an enlarged view of area A1 of FIG. 3;

FIG. 5 is a schematic cross-sectional view illustrating a cross section taken along the line X2-X2′ of FIG. 4;

FIG. 6 is a graph illustrating resonance of blue light and green yellow light depending on a thickness of an organic material layer;

FIG. 7 is an enlarged cross-sectional view of a light emitting element of the display device according to one or more embodiments;

FIG. 8 is an enlarged cross-sectional view of a light emitting element of a display device according to one or more embodiments;

FIG. 9 is a cross-sectional view illustrating a portion of the display device according to one or more embodiments; and

FIG. 10 is an enlarged view of area A3 of FIG. 9.

### DETAILED DESCRIPTION

The invention will now be described more fully hereinafter with reference to the accompanying drawings, in which embodiments of present disclosure are shown. This invention may, however, be embodied in different forms and should not be construed as limited to one or more embodiments set forth herein. Rather, these embodiments are provided so that this disclosure will be thorough and complete, and will fully convey the scope of present disclosure to those skilled in the art.

It will also be understood that if (e.g., when) a layer is referred to as being “on” another layer or substrate, it can be directly on the other layer or substrate, or intervening layers may also be present. The same reference numbers indicate the same components throughout the specification.

It will be understood that, although the terms “first,” “second,” and/or the like. may be used herein to describe one or more suitable elements, these elements should not be limited by these terms. These terms are only used to distinguish one element from another element. For instance, a first element discussed could be termed a second element without departing from the teachings of present disclosure. Similarly, the second element could also be termed the first element.

In the present specification, “including A or B”, “A and/or B”, etc., represents A or B, or A and B.

As used herein, the term “and/or” includes any and all combinations of one or more of the associated listed items. As used herein, expressions such as “at least one of”, “one of”, and “selected from”, when preceding a list of elements, modify the entire list of elements and do not modify the individual elements of the list. For example, “at least one of a, b or c”, “at least one selected from a, b and c”, etc., may indicate only a, only b, only c, both (e.g., simultaneously) a and b, both (e.g., simultaneously) a and c, both (e.g., simultaneously) b and c, all of a, b, and c, or variations thereof.

As used herein, the term “substantially,” “about,” and similar terms are used as terms of approximation and not as terms of degree, and are intended to account for the inherent deviations in measured or calculated values that would be recognized by those of ordinary skill in the art. “Substantially” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “substantially” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.” As used herein, the singular forms “a,” “an” and “the” are intended to include the plural forms as well, unless the context clearly indicates otherwise.

Descriptions of features or aspects within each embodiment should typically be considered as available for other similar features or aspects in other embodiments. In the context of the present application and unless otherwise defined, the terms “use,” “using,” and “used” may be considered synonymous with the terms “utilize,” “utilizing,” and “utilized,” respectively. Further, the use of “may” when describing embodiments of the present invention refers to “one or more embodiments of the present invention.”

Hereinafter, embodiments will be described in more detail with reference to the accompanying drawings.

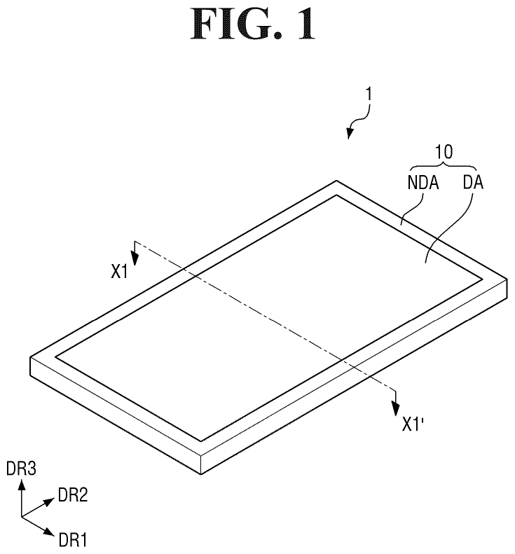

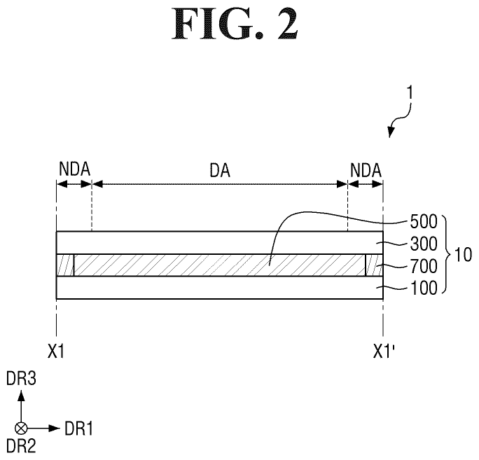

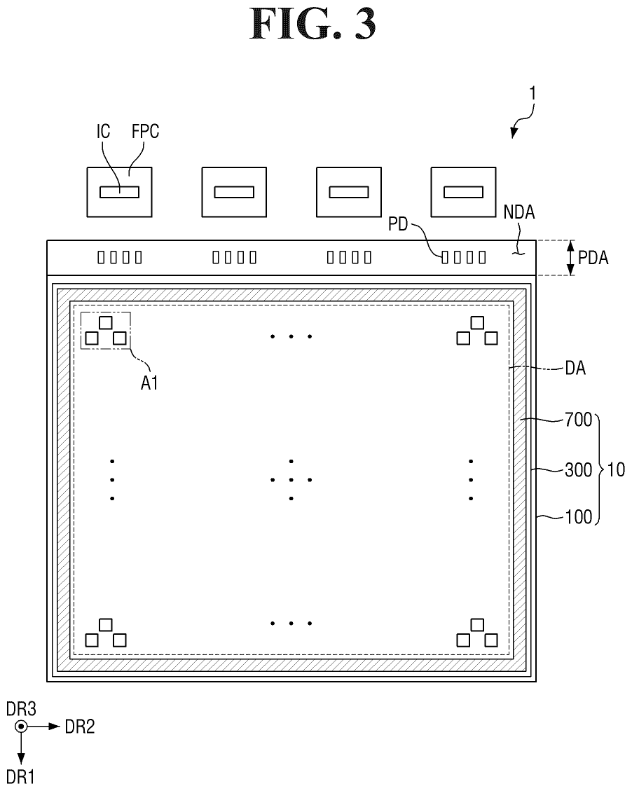

FIG. 1 is a perspective view illustrating a display device according to one or more embodiments. FIG. 2 is a schematic cross-sectional view illustrating a cross section taken along the line X1-X1′ of FIG. 1. FIG. 3 is a plan view of the display device according to one or more embodiments.

Referring to FIGS. 1 and 2, a display device 1 according to one or more embodiments may be applied to portable electronic devices such as mobile phones, smartphones, tablet personal computers (PCs), mobile communication terminals, electronic notebooks, electronic books, portable multimedia players (PMPs), navigation devices, and/or ultra mobile PCs (UMPCs). In one or more embodiments, the display device 1 according to one or more embodiments may be applied as a display unit of television(s), laptop computer(s), monitor(s), billboard(s), and/or the Internet of Thing(s) (IoT). These electronic devices are provided only as examples, and the display device 1 may also be adopted in other electronic devices without departing from the concept of the present disclosure.

In FIG. 1, a first direction DR1, a second direction DR2, and a third direction DR3 are defined. The first direction DR1 and the second direction DR2 may be normal (e.g., perpendicular) to each other, the first direction DR1 and the third direction DR3 may be normal (e.g., perpendicular) to each other, and the second direction DR2 and the third direction DR3 may be normal (e.g., perpendicular) to each other. It may be understood that the first direction DR1 refers to a longitudinal direction in the drawing, the second direction DR2 refers to a transverse direction in the drawing, and the third direction DR3 refers to upward and downward directions, that is, a thickness direction, in the drawing. In the following specification, unless otherwise specified, the term “direction” may refer to both (e.g., simultaneously) directions toward both sides (e.g., opposite sides) extending along the direction. In addition, if (e.g., when) both (e.g., simultaneously) “directions” extending to both sides (e.g., opposite sides) need to be distinguished from each other, one side will be referred to as “one side in the direction” and the other side will be referred to as “the other side in the direction”. In FIG. 1, an arrow direction will be referred to as one side, and an opposite direction to the arrow direction will be referred to as the other side. In addition, the third direction DR3 may be referred to as a thickness direction.

Hereinafter, for convenience of explanation, in referring to surfaces of a display device 1 or respective members constituting the display device 1, one surface opposite to (e.g., facing) one side in a direction in which an image is displayed, that is, the third direction DR3 will be referred to as an upper surface, and a surface opposite to the one surface will be referred to as a lower surface. However, the present disclosure is not limited thereto, and the one surface and the other surface of the member may be referred to as a front surface and a rear surface, respectively. In addition, in describing relative positions of the respective members of the display device 1, one side in the third direction DR3 may be referred to as an upper portion and the other side in the third direction DR3 may be referred to as a lower portion.

The display device 1 has a three-dimensional shape. For example, the display device 1 may have a rectangular parallelepiped shape or a three-dimensional shape similar to the rectangular parallelepiped shape. In one or more embodiments, the display device 1 according to one or more embodiments may have a shape similar to a rectangular shape in a plan view. For example, the display device 1 according to one or more embodiments may have a shape similar to a rectangular shape, in the plan view, having short sides in the first direction DR1 and long sides in the second direction DR2, as illustrated in FIG. 1, but the present disclosure is not limited thereto. For example, a shape of the display device 1 according to one or more embodiments in plan view may be a shape in which a corner where the short side in the first direction DR1 and the long side in the second direction DR2 meet may be rounded with a set or predetermined curvature or right-angled or is not limited to the rectangular shape and may be a shape similar to other polygonal shapes, a circular shape, or an elliptical shape.

The display device 1 may further include a display panel 10, flexible circuit boards FPC, and driving chips IC. The display panel may include a display area DA where a screen is displayed and a non-display area NDA where the screen is not displayed. In one or more embodiments, the non-display area NDA may be arranged to be around (e.g., surround) edges of the display area DA, but the present disclosure is not limited thereto. An image displayed in the display area DA may be viewed by a user on one side of the third direction DR3 in FIG. 1.

The display panel 10 may include a light emitting unit 100 and a light transmitting unit 300 opposite to (e.g., facing) the light emitting unit 100, as illustrated in FIG. 2, and may further include a sealing member 700 coupling the light emitting unit 100 and the light transmitting unit 300 to each other and a filling unit 500 filled between the light emitting unit 100 and the light transmitting unit 300.

The light emitting unit 100 may include elements and circuits for displaying an image, for example, pixel circuits such as switching elements, a pixel defining film 170 defining an emission area and a non-emission area to be described in more detail later in the display area DA, and self-light emitting elements. In one or more embodiments, the self-light emitting element may include at least one of an organic light emitting diode, a quantum dot light emitting diode, an inorganic material-based micro light emitting diode (e.g., a micro LED), or a nano-sized inorganic material-based light emitting diode (e.g., a nano LED). Hereinafter, for convenience of explanation, a case where the self-light emitting element is an organic light emitting diode will be described in more detail by way of example.

The light transmitting unit 300 may be positioned on the light emitting unit 100, and may face the light emitting unit 100. In one or more embodiments, the light transmitting unit 300 may include a color conversion pattern converting a color of incident light emitted from the light emitting unit 100 and irradiated to the light transmitting unit 300. In one or more embodiments, the light transmitting unit 300 may include at least one of a color filter layer 320 or a light transmitting member to be described in more detail later as the color conversion pattern. In one or more embodiments, the light transmitting unit 300 may also include both (e.g., simultaneously) the color filter layer 320 and the light transmitting member. The light transmitting member may include at least one of wavelength conversion shifters or light scatterers, as described in more detail later.

The sealing member 700 may be positioned between the light emitting unit 100 and the light transmitting unit 300 in the non-display area NDA. The sealing member 700 may be arranged along edges of the light emitting unit 100 and the light transmitting unit 300 in the non-display area NDA to be around (e.g., surround) the display area DA in the plan view. The light emitting unit 100 and the light transmitting unit 300 may be coupled to each other via the sealing member 700.

In one or more embodiments, the sealing member 700 may be made of an organic material. As an example, the sealing member 700 may be made of an epoxy-based resin, but the present disclosure is not limited thereto. In one or more embodiments, the sealing member 700 may also have a form of a frit including glass and/or the like.

The filling unit 500 may be positioned in a space between the light emitting unit 100 and the light transmitting unit 300 surrounded by the sealing member 700 (e.g., the sealing member 700 may be around or may surround the light transmitting unit 300). The filling unit 500 may fill the space between the light emitting unit 100 and the light transmitting unit 300.

In one or more embodiments, the filling unit 500 may be made of a material that may be configured to transmit light therethrough. In one or more embodiments, the filling unit 500 may be made of an organic material. For example, the filling unit 500 may be made of a silicone organic material, an epoxy-based organic material, a mixture of a silicone organic material and an epoxy-based organic material, and/or the like.

Referring to FIG. 3, the display device 1 may further include the flexible circuit boards FPC and the driving chips IC in addition to the display panel 10.

The non-display area NDA of the display panel 10 may include a pad area PDA, and a plurality of connection pads PD may be positioned in the pad area PDA. The pad area PDA may be defined on the light emitting unit 100. Accordingly, the plurality of connection pads PD may be arranged on the light emitting unit 100.

The flexible circuit boards FPC may be connected to the connection pads PD. The flexible circuit boards FPC may electrically connect a circuit board and the light emitting unit 100. The circuit board provides signals, power, and/or the like, for driving the display device 1.

The driving chips IC may be electrically connected to the circuit board and/or the like to receive data, signals, and/or the like. In one or more embodiments, the driving chip IC may be a data driving chip, and may receive data control signals, image data, and/or the like, from the circuit board and/or the like and generate and output data voltages and/or the like corresponding to the image data.

In one or more embodiments, the driving chip IC may be mounted on the flexible circuit board FPC. For example, the driving chip IC may be mounted on the flexible circuit board FPC in the form of a chip on film (COF).

The data voltages provided from the driving chips IC, the power provided from the circuit board, and/or the like, may be transferred to the pixel circuits and/or the like of the light emitting unit 100 via the flexible circuit boards FPC and the connection pads PD.

Hereinafter, a plurality of emission areas defined in the light emitting unit 100 of the display panel 10 and a plurality of light transmitting areas defined in the light transmitting unit 300 of the display panel 10 will be described in more detail.

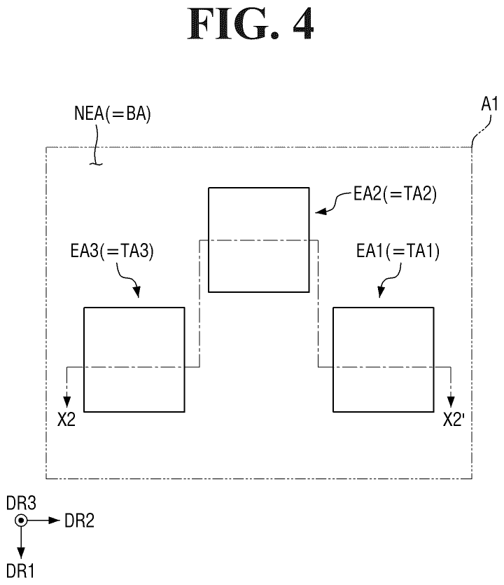

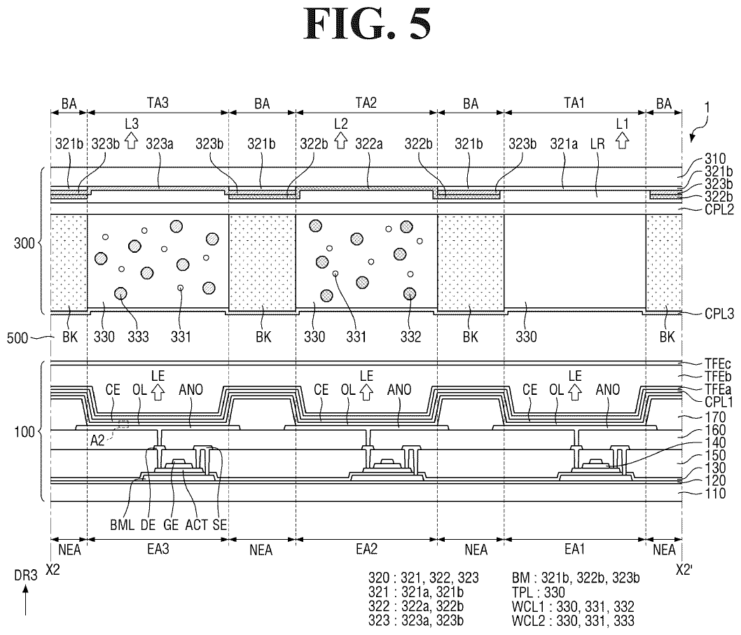

FIG. 4 is an enlarged plan view of area A1 of FIG. 3. More specifically, FIG. 4 is a schematic plan view of one pixel group in the display panel of FIG. 3. FIG. 5 is a schematic cross-sectional view illustrating a cross section taken along the line X2-X2′ of FIG. 4.

Referring to FIG. 5 in addition to FIG. 4, a plurality of emission areas EA1, EA2, and EA3 may be defined in the light emitting unit 100 of the display device 1 according to one or more embodiments, and a plurality of light transmitting areas TA1, TA2, and TA3 may be defined in the light transmitting unit 300 of the display device 1.

The display area DA and the non-display area NDA defined in the display device 1 may be applied to the light emitting unit 100 and the light transmitting unit 300.

A first emission area EA1, a second emission area EA2, and a third emission area EA3 may be defined in the display area DA of the light emitting unit 100, as illustrated in FIG. 4. The first emission area EA1, the second emission area EA2, and the third emission area EA3 may be areas where light generated by light emitting elements of the light emitting unit 100 is emitted to the outside of the light emitting unit 100, and a non-emission area NEA may be an area where light is not emitted to the outside of the light emitting unit 100. In one or more embodiments, the non-emission area NEA may be around (e.g., surround) the first emission area EA1, the second emission area EA2, and the third emission area EA3 within the display area DA, but the present disclosure is not limited thereto.

In one or more embodiments, light emitted from the first emission area EA1, the second emission area EA2, and the third emission area EA3 to the outside may be light of a first color. In one or more embodiments, the light of the first color may be blue light. In one or more embodiments, the light of the first color may be mixed light, and may be mixed light of two or more of (e.g., selected from among) blue light, green light, and red light. In one or more embodiments, the light of the first color may be white light obtained by mixing blue light and green yellow light with each other or white light obtained by mixing blue light and yellow light with each other. The red light may have a peak wavelength in the range of about 610 nm to about 650 nm, the green light may have a peak wavelength in the range of about 510 nm to about 550 nm, the blue light may have a peak wavelength in the range of about 440 nm to about 480 nm, the yellow light may have a peak wavelength in the range of about 570 nm to about 610 nm, and the green yellow light may have a peak wavelength in the range of about 530 nm to about 560 nm. Here, the peak wavelength refers to a wavelength at which intensity of light is highest.

In one or more embodiments, as illustrated in FIG. 4, the first emission area EA1 and the third emission area EA3 may be sequentially positioned along the second direction DR2 and the second emission area EA2 may be positioned on one side of a space between the first emission area EA1 and the third emission area EA3 spaced and/or apart (e.g., spaced apart or separated) from each other, such that the first emission area EA1, the second emission area EA2, and the third emission area EA3 may form one group, and as illustrated in FIG. 3, one group formed by the first emission area EA1, the second emission area EA2, and the third emission area EA3 may be repeatedly arranged along the first direction DR1 and the second direction DR2 within the display area DA, but the present disclosure is not limited thereto. For example, an arrangement of the first emission area EA1, the second emission area EA2, and the third emission area EA3 can be variously or suitably changed, such that the first emission area EA1, the second emission area EA2, and the third emission area EA3 may be sequentially positioned along the second direction DR2. Hereinafter, for convenience of explanation, a case where the first emission area EA1, the second emission area EA2, and the third emission area EA3 are arranged as illustrated in FIG. 4 will be described in more detail by way of example.

In one or more embodiments, an area of the first emission area EA1, an area of the second emission area EA2, and an area of the third emission area EA3 may be substantially the same as each other, but the present disclosure is not limited thereto. For example, an area of the first emission area EA1, an area of the second emission area EA2, and an area of the third emission area EA3 may also be different from each other. In one or more embodiments, the first emission area EA1, the second emission area EA2, and the third emission area EA3 may (e.g., may each) have a square shape in a plan view, but the present disclosure is not limited thereto. Hereinafter, for convenience of explanation, it will be mainly described that the first emission area EA1, the second emission area EA2, and the third emission area EA3 (e.g., may each) have a square shape in the plan view and have substantially the same area.

A first light transmitting area TA1, a second light transmitting area TA2, and a third light transmitting area TA3 may be defined in the display area DA of the light transmitting unit 300. The first light transmitting area TA1, the second light transmitting area TA2, and the third light transmitting area TA3 may be areas where light generated in the first emission area EA1, the second emission area EA2, and the third light transmitting area EA3 is transmitted. A light blocking area BA may be positioned around the first light transmitting area TA1, the second light transmitting area TA2, and the third light transmitting area TA3 within the display area DA of the light transmitting unit 300. In one or more embodiments, the light blocking area BA may be around (e.g., surround) the first light transmitting area TA1, the second light transmitting area TA2, and the third light transmitting area TA3, but the present disclosure is not limited thereto. For example, the light blocking area BA may be positioned not only in the display area DA of the light transmitting unit 300 but also in the non-display area NDA of the light transmitting unit 300.

The first light transmitting area TA1 may correspond to and overlap the first emission area EA1, the second light transmitting area TA2 may correspond to and overlap the second emission area EA2, and the third light transmitting area TA3 may correspond to and overlap the third emission area EA3. In one or more embodiments, the first light transmitting area TA1 may have substantially the same area as the first emission area EA1 and completely overlap the first emission area EA1, the second light transmitting area TA2 may have substantially the same area as the second emission area EA2 and completely overlap the second emission area EA2, and the third light transmitting area TA3 may have substantially the same area as the third emission area EA3 and completely overlap the third emission area EA3, but the present disclosure is not limited thereto. For example, the first light transmitting area TA1 may have an area different from that of the first emission area EA1, the second light transmitting area TA2 may have an area different from that of the second emission area EA2, and the third light transmitting area TA3 may have an area different from that of the third emission area EA3. Hereinafter, for convenience of explanation, it will be mainly described that the first light transmitting area TA1 has substantially the same area as the first emission area EA1 and completely overlaps the first emission area EA1, the second light transmitting area TA2 has substantially the same area as the second emission area EA2 and completely overlaps the second emission area EA2, and the third light transmitting area TA3 has substantially the same area as the third emission area EA3 and completely overlaps the third emission area EA3.

The first light transmitting area TA1 and the third light transmitting area TA3 may be sequentially positioned along the second direction DR2 and the second light transmitting area TA2 may be positioned on one side of a space between the first light transmitting area TA1 and the third light transmitting area TA3 spaced and/or apart (e.g., spaced apart or separated) from each other, such that the first light transmitting area TA1, the second light transmitting area TA2, and the third light transmitting area TA3 may form one pixel group. In addition, as illustrated in FIG. 3, a plurality of pixel groups may be repeatedly arranged along the first direction DR1 and the second direction DR2 within the display area DA.

As described above, the light of the first color provided from the light emitting unit 100 may be transmitted through the first light transmitting area TA1, the second light transmitting area TA2, and the third light transmitting area TA3 and then provided to the outside of the display device 1. The light emitted from the first light transmitting area TA1 to the outside of the display device 1 may be referred to as first emitted light L1, and the light emitted from the second light transmitting area TA2 to the outside of the display device 1 may be referred to as second emitted light L2, and the light emitted from the third light transmitting area TA3 to the outside of the display device 1 may be referred to as third emitted light L3. The first emitted light L1 may be the light of the first color, the second emitted light L2 may be light of a second color, and the third emitted light L3 may be light of a third color. In one or more embodiments, the light of the first color may be blue light, the light of the second color may be green light, and the light of the third color may be red light.

Hereinafter, a structure of the display device 1 will be described in more detail.

Referring to FIG. 5, as described above, the display device 1 may include the light emitting unit 100, the light transmitting unit 300 arranged on the light emitting unit 100 and opposite to (e.g., facing) the light emitting unit 100, and the filling unit 500 interposed between the light emitting unit 100 and the light transmitting unit 300. Hereinafter, for convenience of explanation, the light emitting unit 100, the light transmitting unit 300, and the filling unit 500 will be sequentially described.

The light emitting unit 100 may have a structure in which a first substrate 110, a buffer layer 120, bottom metal layers BML, a first insulating layer 130, semiconductor layers ACT, gate electrodes GE, a gate insulating layer 140, a second insulating layer 150, source/drain electrodes, a third insulating layer 160, light emitting elements, a pixel defining film 170, a first capping layer CPL1, and a thin film encapsulation layer are sequentially stacked on one side in the third direction DR3.

The first substrate 110 of the light emitting unit 100 may serve as a base of the light emitting unit 100. The first substrate 110 may be made of a material having light transmitting properties. The first substrate 110 may be a glass substrate and/or a plastic substrate. When the first substrate 110 is the plastic substrate, the first substrate 110 may have flexibility. In one or more embodiments, if (e.g., when) the first substrate 110 is the plastic substrate, the first substrate 110 may include polyimide, but the present disclosure is not limited thereto.

The buffer layer 120 of the light emitting unit 100 may be arranged on the first substrate 110. The buffer layer 120 may serve to block (or protect from) foreign substance(s) and/or moisture permeating into elements arranged on the buffer layer 120 through the first substrate 110.

In one or more embodiments, the buffer layer 120 may include an inorganic material such as SiO₂, SiNₓ, or SiOₓN_{y}, and may be formed as a single layer or multiple layers, but the present disclosure is not limited thereto.

The bottom metal layer BML of the light emitting unit 100 may be arranged on the buffer layer 120. The bottom metal layer BML may block external light or light emitted from a light emitting element to be described in more detail later from being introduced into the semiconductor layer ACT. Accordingly, it is possible to prevent or reduce generation of a leakage current due to light in a thin film transistor to be described in more detail later or reduce the generation of the leakage current.

The bottom metal layer BML may be made of a material blocking light and having conductivity. In one or more embodiments, the bottom metal layer BML may include a single material of metals such as silver (Ag), nickel (Ni), gold (Au), platinum (Pt), aluminum (Al), copper (Cu), molybdenum (Mo), and titanium (Ti), or alloys thereof.

In one or more embodiments, the bottom metal layer BML may have a single-layer or multilayer structure. For example, if (e.g., when) the bottom metal layer BML has the multilayer structure, the bottom metal layer BML may be a stacked structure of titanium (Ti)/copper (Cu)/indium tin oxide (ITO) or a stacked structure of titanium (Ti)/copper (Cu)/aluminum oxide (Al₂O₃), but the present disclosure is not limited thereto.

In one or more embodiments, a plurality of bottom metal layers BML may be provided to correspond to respective semiconductor layers ACT, and may overlap the semiconductor layers ACT. In one or more embodiments, a width of the bottom metal layer BML may be greater than a width of the semiconductor layer ACT.

In one or more embodiments, the bottom metal layer BML may be a portion of a data line, a power supply line, a line electrically connecting a thin film transistor (not illustrated in FIG. 5) and a thin film transistor (illustrated in FIG. 5) GE, ACT, DE, and SE (see FIG. 5) to each other, and/or the like. In one or more embodiments, the bottom metal layer BML may be made of a material having a lower resistance than a source electrode SE and a drain electrode DE.

The first insulating layer 130 of the light emitting unit 100 may be arranged on the bottom metal layers BML. The first insulating layer 130 may serve to electrically insulate the bottom metal layers BML and the semiconductor layers ACT from each other. The first insulating layer 130 may cover the bottom metal layers BML.

In one or more embodiments, the first insulating layer 130 may include an inorganic material such as SiO₂, SiNₓ, SiOₓN_{y}, Al₂O₃, TiO₂, Ta₂O, HfO₂, and/or ZrO₂, but the present disclosure is not limited thereto.

The semiconductor layers ACT of the light emitting unit 100 may be arranged on the first insulating layer 130. The semiconductor layers ACT may be arranged to correspond to the first emission area EA1, the second emission area EA2, and the third emission area EA3, respectively, within the display area DA of the light emitting unit 100. In addition, the semiconductor layers ACT may be arranged to overlap the respective bottom metal layers BML, and accordingly, generation of photocurrents in the semiconductor layers ACT may be suppressed or reduced.

The semiconductor layer ACT may include an oxide semiconductor. In one or more embodiments, the semiconductor layer ACT may be made of Zn oxide, In—Zn oxide, Ga—In—Zn oxide, and/or the like, which is a zinc (Zn) oxide-based material, or may be made of an In—Ga—Zn—O (IGZO) semiconductor in which metals such as indium (In) and/or gallium (Ga) are contained in ZnO, but the present disclosure is not limited thereto. For example, the semiconductor layer ACT may include amorphous silicon, polysilicon, and/or the like.

The gate electrode GE of the light emitting unit 100 may be arranged on the semiconductor layer ACT. The gate electrode GE may be arranged to overlap the semiconductor layer ACT in the display area DA. In one or more embodiments, a width of the gate electrode GE may be smaller than the width of the semiconductor layer ACT, but the present disclosure is not limited thereto.

In one or more embodiments, the gate electrode GE may include one or more of aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu) in consideration of adhesion with an adjacent layer, surface flatness of a layer to be stacked, and workability, and/or the like, and may be formed as a single layer or multiple layers, but the present disclosure is not limited thereto.

The gate insulating layer 140 of the light emitting unit 100 may be arranged between the semiconductor layer ACT and the gate electrode GE. The gate insulating layer 140 may serve to insulate the semiconductor layer ACT and the gate electrode GE from each other. In one or more embodiments, the gate insulating layer 140 may be formed in a shape in which it is partially patterned on one side of the first substrate 110 in the third direction DR3, and may have a width smaller than that of the semiconductor layer ACT and greater than that of the gate electrode GE, but the present disclosure is not limited thereto.

In one or more embodiments, the gate insulating layer 140 may include an inorganic material. For example, the gate insulating layer 140 may include the inorganic material exampled in the description of the first insulating layer 130.

The second insulating layer 150 of the light emitting unit 100 may be arranged on the gate insulating layer 140 to cover the semiconductor layer ACT and the gate electrode GE. In one or more embodiments, the second insulating layer 150 may function as a planarization film providing a flat surface.

1 The second insulating layer 150 may include an organic material. In one or more embodiments, the second insulating layer 150 may include at least one of photo acryl (PAC), polystylene, polymethyl methacrylate (PMMA), polyacrylonitrile (PAN), polyamide, polyimide, polyarylether, a heterocyclic polymer, parylene, a fluorine-based polymer, an epoxy resin, a benzocyclobutene-based resin, a siloxane-based resin, or a silane resin, but the present disclosure is not limited thereto.

The source electrode SE and drain electrode DE of the light emitting unit 100 may be spaced and/or apart (e.g., spaced apart or separated) from each other and arranged on the second insulating layer 150. The source electrode SE and the drain electrode DE may each be connected to the semiconductor layer ACT through contact holes penetrating through the second insulating layer 150. In one or more embodiments, the source electrode SE may penetrate through not only the second insulating layer 150 but also the first insulating layer 130 and be connected to the bottom metal layer BML. When the bottom metal layer BML is a portion of a line transferring a signal, a voltage, and/or the like, the source electrode SE may be connected to and electrically coupled to the bottom metal layer BML to receive the voltage and/or the like provided to the line. In one or more embodiments, if (e.g., when) the bottom metal layer BML is a floating pattern rather than a separate line, a voltage and/or the like provided to the source electrode SE may be transferred to the bottom metal layer BML and/or the like.

The source electrode SE and drain electrode DE may include aluminum (Al), copper (Cu), titanium (Ti), and/or the like, and may be formed as multiple layers or a single layer. In one or more embodiments, the source electrode SE and the drain electrode DE may have a multilayer structure of Ti/Al/Ti, but the present disclosure is not limited thereto.

The semiconductor layer ACT, the gate electrode GE, the source electrode SE, and the drain electrode DE described above may constitute a thin film transistor, which is a switching element. In one or more embodiments, the thin film transistors may be positioned in the first emission area EA1, the second emission area EA2, and the third emission area EA3, respectively. In one or more embodiments, a portion of the thin film transistor may be positioned in the non-emission area NEA.

The third insulating layer 160 of the light emitting unit 100 may be arranged on the second insulating layer 150 to cover the thin film transistor. In one or more embodiments, the third insulating layer 160 may be a planarization film.

The third insulating layer 160 may be made of an organic material. In one or more embodiments, the third insulating layer 160 may include an acrylic resin, an epoxy-based resin, an imide-based resin, an ester-based resin, and/or the like, or a photosensitive organic material, but the present disclosure is not limited thereto.

A plurality of anode electrodes ANO may be positioned on the third insulating layer 160 in the display area DA of the light emitting unit 100. The respective anode electrodes ANO may be spaced and/or apart (e.g., spaced apart or separated) from each other.

The anode electrodes ANO may overlap the first emission area EA1, the second emission area EA2, and the third emission area EA3, respectively, and at least portions of the anode electrodes ANO may extend to the non-emission area NEA. The anode electrodes ANO may be connected to the drain electrodes DE of the thin film transistors.

In one or more embodiments, the anode electrode ANO may be a reflective electrode, and in this case, the anode electrode ANO may be a metal layer including a metal such as Ag, Mg, Al, Pt, Pd, Au, Ni, Nd, Ir, and/or Cr. In one or more embodiments, the anode electrode ANO may further include a metal oxide layer stacked on the metal layer. In one or more embodiments, the anode electrode ANO may have a multilayer structure such as a double-layer structure of ITO/Ag, Ag/ITO, ITO/Mg, or ITO/MgF or a triple-layer structure of ITO/Ag/ITO.

In one or more embodiments, the plurality of anode electrodes ANO may have the same thickness. In one or more embodiments, some of the plurality of anode electrodes ANO may have a different thickness from the other anode electrodes ANO.

The pixel defining film 170 of the light emitting unit 100 may be arranged on the anode electrodes ANO. The pixel defining film 170 may define the first emission area EA1, the second emission area EA2, and the third emission area EA3 as openings exposing the anode electrodes ANO. The pixel defining film 170 may overlap edges of the anode electrodes ANO.

The pixel defining film 170 may overlap a light blocking area BA of a color filter layer 320 to be described in more detail later in the third direction DR3. In addition, the pixel defining film 170 may also overlap a bank pattern BK to be described in more detail later in the third direction DR3.

In one or more embodiments, the pixel defining film 170 may include an organic insulating material such as a polyacrylates resin, an epoxy resin, a phenolic resin, a polyamides resin, a polyimides resin, an unsaturated polyesters resin, a polyphenyleneethers resin, a polyphenylenesulfides resin, or benzocyclobutene (BCB), but the present disclosure is not limited thereto.

A light emitting layer OL of the light emitting unit 100 may be arranged on the anode electrodes ANO. In one or more embodiments, the light emitting layer OL may have a shape of a substantially continuous film formed across the plurality of emission areas and the non-emission area NEA. In one or more embodiments, the light emitting layer OL may be positioned only within the display area DA, but the present disclosure is not limited thereto. For example, a portion of the light emitting layer OL may also be further arranged within the non-display area NDA. The light emitting layer OL will be described in more detail later.

A cathode electrode CE of the light emitting unit 100 may be arranged on the light emitting layer OL. In one or more embodiments, the cathode electrode CE may be arranged on the light emitting layer OL and have a shape of a substantially continuous film formed across the plurality of emission areas EA1, EA2, and EA3 and the non-emission area NEA. For example, the cathode electrode CE may completely cover the light emitting layer OL.

The cathode electrode CE may have transflective properties or transmissive properties. When a thickness of the cathode electrode CE is several tens to several hundreds of angstroms, the cathode electrode CE may have the transflective properties. In one or more embodiments, if (e.g., when) the cathode electrode CE has the transflective properties, the cathode electrode CE may include Ag, Mg, Cu, Al, Pt, Pd, Au, Ni, Nd, Ir, Cr, Li, Ca, LiF/Ca, LiF/Al, Mo, Ti or compounds or mixtures thereof, for example, a mixture of Ag and Mg. In one or more embodiments, the cathode electrode CE may have transmissive properties by including transparent conductive oxide. In one or more embodiments, if (e.g., when) the cathode electrode CE has the above-described transmissive properties, the cathode electrode CE may include tungsten oxide (WₓOₓ), titanium oxide (TiO₂), indium tin oxide (ITO), indium zinc oxide (IZO), zinc oxide (ZnO), indium tin zinc oxide (ITZO), magnesium oxide (MgO), and/or the like.

The anode electrodes ANO, the light emitting layer OL, and the cathode electrode CE may constitute the light emitting elements. For example, the anode electrode ANO, the light emitting layer OL, and the cathode electrode CE that overlap the first emission area EA1 may constitute a first light emitting element, the anode electrode ANO, the light emitting layer OL, and the cathode electrode CE that overlap the second emission area EA2 may constitute a second light emitting element, and the anode electrode ANO, the light emitting layer OL, and the cathode electrode CE that overlap the third emission area EA3 may constitute a third light emitting element. The first light emitting element, the second light emitting element, and the third light emitting element may each be configured to emit light LE.

According to one or more embodiments, each light emitting element may be a tandem-type or kind light emitting element and may be configured to emit mixed light in which two or more component lights are mixed with each other. A plurality of component lights have differences of periods and micro-cavity, such that a white angle difference may be observed depending on an viewing angle or efficiency of emitted light of a specific color may be reduced.

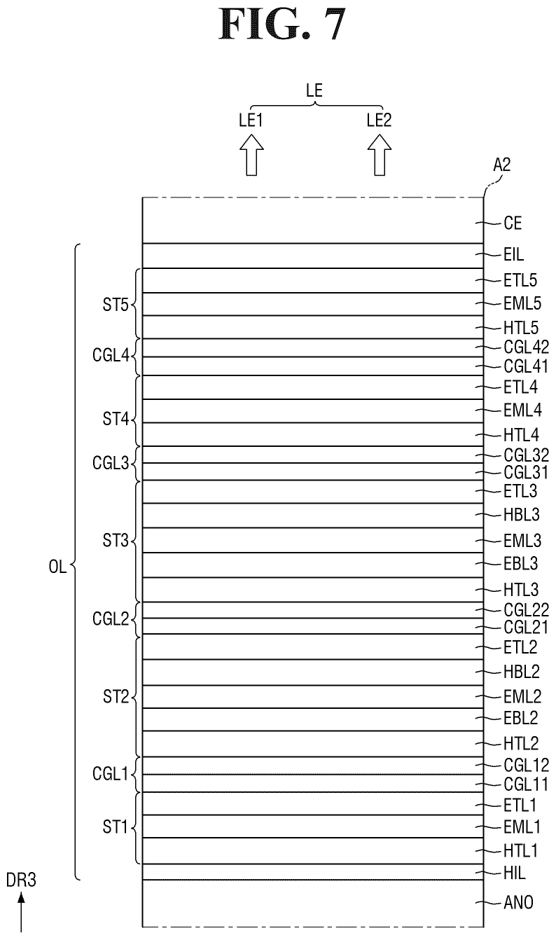

When the light emitting elements are configured utilizing resonance in an area where waves of the component lights overlap each other, it is possible to reduce the white angle difference depending on the viewing angle and increase light efficiency. The light emitting element of the display device 1 according to one or more embodiments may be a tandem-type or kind light emitting element emitting first component light LE1 (see FIG. 7) and second component light LE2 (see FIG. 7), and resonance areas of the first component light LE1 and the second component light LE2 may overlap each other. The light emitting element may have an optimal or suitable thickness of an organic material layer or an electrode so that an N-th resonance area of the first component light LE1 overlaps an M-th resonance area of the second component light LE2. Here, N and M may be the same positive integer or different positive integers. 80% or more of a resonance area of any one of the first component light LE1 and the second component light LE2 may overlap a resonance area of the other of the first component light LE1 and the second component light LE2.

In one or more embodiments, the emitted light LE emitted from the light emitting element may be white light, the first component light LE1 may be blue light, and the second component light LE2 may be yellow light or green yellow light.

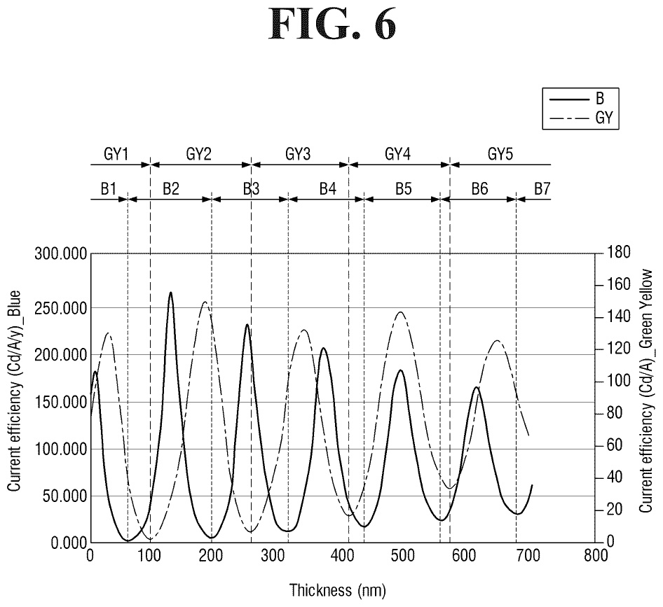

FIG. 6 is a graph illustrating resonance of first component light LE1 and second component light LE2 depending on a thickness of an organic material layer of the light emitting element included in the display device according to one or more embodiments. For example, FIG. 6 illustrates results obtained by measuring or simulating a change in current efficiency depending on a thickness of the organic material layer for blue light B and green yellow light GY. Here, the thickness of the organic material layer may be the sum of thicknesses of layers (e.g., a hole transport layer, a hole injection layer, an electron transport layer, a charge generation layer, and/or the like) arranged between the anode electrode ANO and a light emitting material layer EML.

Current efficiency of the blue light B and the green yellow light GY increases or decreases depending on the thickness of the organic material layer such as a hole transport layer HTL. Resonance areas may be defined based on points where the current efficiency decreases and then increases. Referring to FIG. 6, the blue light B may have a first resonance area B1 in a section in which the thickness of the organic material layer is 0 to about 60 nm, a second resonance area B2 in a section in which the thickness of the organic material layer is about 60 nm to about 190 nm, a third resonance area B3 in a section in which the thickness of the organic material layer is about 190 nm to about 310 nm, a fourth resonance area B4 in a section in which the thickness of the organic material layer is about 310 nm to about 440 nm, a fifth resonance area B5 in a section in which the thickness of the organic material layer is about 440 nm to about 560 nm, a sixth resonance area B6 in a section in which the thickness of the organic material layer is about 560 nm to about 680 nm, and a seventh resonance area B7 in a section in which the thickness of the organic material layer exceeds about 680 nm. In addition, the green yellow light GY may have a first resonance area GY1 in a section in which the thickness of the organic material layer is 0 to about 100 nm, a second resonance area GY2 in a section in which the thickness of the organic material layer is about 100 nm to about 250 nm, a third resonance area GY3 in a section in which the thickness of the organic material layer is about 250 nm to about 410 nm, a fourth resonance area GY4 in a section in which the thickness of the organic material layer is about 410 nm to about 570 nm, and a fifth resonance area GY5 in a section in which the thickness of the organic material layer exceeds about 570 nm.

Referring to FIG. 6, it can be seen that an entire section of the fifth resonance area B5 of the blue light B overlaps the fourth resonance area GY4 of the green yellow light GY. The light emitting element may be constructed based on a section where the resonance areas of the two component lights overlap each other.

An efficiency change depending on the thickness may be measured using a QD-1000 IVL equipment available from ENC Technology Inc., and simulated or calculated through a SETFOS3.2 program. The respective layers are configured at the same thicknesses as those in an actual element in the SETFOS3.2 program by measuring a refractive index (n) and an absorptivity (k) value with an ellipsometer equipment and then utilizing the refractive index and the absorptivity value. PL spectra of the first component light (or the blue light) and the second component light (or the green yellow light) may be extracted from an integrating sphere spectrum and used as sources. It is possible to simulate resonance efficiency characteristics depending on the thickness of the organic material layer between the anode electrode ANO and the light emitting material layer EML by utilizing the sources.

Thicknesses of the layers of the element may be confirmed through a transmission electron microscope (TEM). It is possible to confirm components and molecular weights of the respective layers while destroying the element from the top using a laser desorption ionization mass spectrometry (LDI-MS). In addition, wavelengths of the spectra may be confirmed through an EL spectrum or a PL spectrum of the panel.

The description of FIG. 6 provided herein is based on a relationship between the resonance areas of the blue light B and the green yellow light GY, but the present disclosure is not limited thereto, and types (kinds) of the emitted light LE and the component lights LE1 and LE2 may be changed. Hereinafter, for convenience, the blue light B and the green yellow light GY illustrated in FIG. 6 will be mainly described.

Referring to FIG. 7, the emitted light LE emitted from the light emitting layer OL may be mixed light in which the first component light LE1 and the second component light LE2 are mixed with each other. In one or more embodiments, the first component light LE1 may be blue light, the second component light LE2 may be green yellow light, and the emitted light LE may be white light. A peak wavelength of the first component light LE1 may be about 440 nm to about 480 nm, and a peak wavelength of the second component light LE2 may be about 530 nm to about 560 nm.

In one or more embodiments, the light emitting layer OL may have a structure in which a plurality of light emitting layers are arranged to overlap each other, as illustrated in FIG. 7, for example, a tandem structure. The tandem structure may include a plurality of stacks each including a hole transport layer HTL, an emitting material layer EML, and an electron transport layer ETL, and the plurality of stacks may be stacked in a thickness direction or a length direction. The light emitting layer OL may include a hole injection layer HIL arranged on the anode electrode ANO, a plurality of stacks ST1, ST2, ST3, ST4, and ST5 arranged on the hole injection layer HIL, and an electron injection layer EIL arranged on the plurality of stacks ST1, ST2, ST3, ST4, and ST5.

The hole injection layer HIL is a layer serving to facilitate the injection of holes from the anode electrode ANO into the stack ST1, ST2, ST3, ST4, and ST5, and a hole injection material is a material having the ability to transport holes from the anode electrode at low voltage and having an excellent or suitable hole injection effect. Examples of the hole injection material may include metal porphyrine, oligothiophene, an arylamine-based organic material, a hexanitrilehexaazatriphenylene-based organic material, a quinacridone-based organic material, a perylene-based organic material, anthraquinone and polyaniline and polythiophene-based conductive polymers, a diamine compound including an aryl group or a heteroaryl group, copper phthalocyanine (CuPc), poly(3,4)-ethylenedioxythiophene (PEDOT), polyaniline (PANI), N,N-dinaphthyl-N,N′-diphenyl benzidine (NPD), and/or the like, but the present disclosure is not limited thereto.

The plurality of stacks may be arranged on the hole injection layer HIL. For example, the light emitting layer OL may include four or more stacks, and two or more component lights may be emitted from the light emitting layer OL. The light emitting layer OL may include two or more stacks that are configured to emit the first component light LE1 and two or more stacks that are configured to emit the second component light LE2.

In one or more embodiments, the light emitting layer OL may include a first stack ST1 including a first light emitting material layer EML1, a second stack ST2 positioned on the first stack ST1 and including a second light emitting material layer EML2, a third stack ST3 positioned on the second stack ST2 and including a third light emitting material layer EML3, a fourth stack ST4 positioned on the third stack ST3 and including a fourth light emitting material layer EML4, a fifth stack ST5 positioned on the fourth stack ST4 and including a fifth light emitting material layer EML5, a first charge generation layer CGL1 positioned between the first stack ST1 and the second stack ST2, a second charge generation layer CGL2 positioned between the second stack ST2 and the third stack ST3, a third charge generation layer CGL3 positioned between the third stack ST3 and the fourth stack ST4, and a fourth charge generation layer CGL4 positioned between the fourth stack ST4 and the fifth stack ST5.

The first to fifth stacks ST1, ST2, ST3, ST4, and ST5 may be arranged to overlap each other. The first to fifth light emitting material layers EML1, EML2, EML3, EML4, and EML5 may be arranged to overlap each other. The first to fifth stacks ST1, ST2, ST3, ST4, and ST5 may be sequentially arranged on the hole injection layer HIL in the thickness direction.

Two of (e.g., selected from among) the first to fifth stacks ST1, ST2, ST3, ST4, and ST5 may be configured to emit the first component light LE1, and the other three of (e.g., selected from among) the first to fifth stacks ST1, ST2, ST3, ST4, and ST5 may be configured to emit the second component light LE2. In one or more embodiments, the first light emitting material layer EML1, the fourth light emitting material layer EML4, and the fifth light emitting material layer EML5 may be configured to emit the second component light LE2, for example, the green yellow light. The second light emitting material layer EML2 and the third light emitting material layer EML3 may be configured to emit the first component light LE1, for example, the blue light. The resonance areas of the blue light of the first component light LE1 and the green yellow light of the second component light LE2 overlap each other, such that even though the display device 10 is viewed from the side, efficiency of the two component lights LE1 and LE2 may decrease equally and a white angle difference depending on an viewing angle may be reduced.

The light emitting material layers of two adjacent stacks of the plurality of stacks ST1, ST2, ST3, ST4, and ST5 may be configured to emit the same type or kind of component light. The two adjacent stacks have one charge generation layer interposed therebetween. For example, the second light emitting material layer EML2 of the second stack ST2 and the third light emitting material layer EML3 of the third stack ST3 may be configured to emit the first component light LE1. In one or more embodiments, the fourth light emitting material layer EML4 of the fourth stack ST4 and the fifth light emitting material layer EML5 of the fifth stack ST5 may be configured to emit the second component light LE2. The present disclosure is not limited thereto, and the two adjacent stacks may be configured to emit the same component light.

In one or more embodiments, each of the second light emitting material layer EML2 and the third light emitting material layer EML2 may include a host and a blue dopant. The host is not particularly limited as long as it is a commonly used material, but one or more selected from among condensed ring derivatives such as anthracene or pyrene, metal chelated oxinoid compounds such as tris(8-quinolinolato)aluminum, bis-styryl derivatives such as bis-styryl anthracene derivatives and distyrylbenzene derivatives, tetraphenylbutadiene derivatives, coumarin derivatives, oxadiazole derivatives, perinone derivatives, cyclopentadiene derivatives, pyrrolopyridine derivatives, pyrrolopyrrole derivatives, thiadiazolopyridine derivatives, and polyphenylenevinylene derivatives, polyparaphenylene derivatives, and polythiophene derivatives in polymer-based derivatives may be used as the host, and one or more substituents such as aryl, heteroaryl, arylvinyl, amino, and/or cyano may be introduced into these derivatives. For example, tris(8-hydroxyquinolino)aluminum (Alq₃), 4,4′-bis(N-carbazolyl)-1,1′-biphenyl (CBP), poly(n-vinylcabazole) (PVK), 9,10-di(naphthalen-2-yl) anthracene (ADN), 4,4′,4″-tris(carbazol-9-yl)-triphenylamine (TCTA), 1,3,5-tris(N-phenylbenzimidazole-2-yl)benzene (TPBi), 3-tert-butyl-9,10-di(naphth-2-yl) anthracene (TBADN), distyryl arylene (DSA), 4,4′-bis(9-carbazolyl)-2,2″-dimethyl-biphenyl (CDBP), 2-methyl-9,10-bis(naphthalen-2-yl) anthracene (MADN), and/or the like, may be used as the host.

The blue dopant is not particularly limited as long as it is a commonly used material, but may include, for example, a fluorescent material including any one selected from among the group including (e.g., consisting of) spiro-DPVBi, spiro-6P, distyryl-benzene (DSB), distyryl-arylene (DSA), a polyfluorene (PFO)-based polymer, a poly(p-phenylene vinylene) (PPV)-based polymer, and a DABNA-based boron polycyclic compound As another example, the blue dopant may include a phosphorescent material including an organometallic complex such as (4,6-F₂ppy)₂Ir(pic). Substituents such as aryl, heteroaryl, arylvinyl, amino, and cyano may be introduced into these compounds exemplified as the blue dopant.

In one or more embodiments, each of the first light emitting material layer EML1, the fourth light emitting material layer EML4, and the fifth light emitting material layer EML5 may include a green yellow host and a green yellow dopant. As the green yellow host, the host materials described above may be used. A material of the green yellow dopant is not particularly limited as long as it is a commonly used material, but may include one or more selected from among coumarin derivatives, phthalimide derivatives, naphthalimide derivatives, perinone derivatives, acridone derivatives, quinacridone derivatives, pyrrolopyrrole derivatives, cyclopentadiene derivatives, naphthacene derivatives such as rubrene, and/or the like, and one or more substituents such as aryl, heteroaryl, arylvinyl, amino, and/or cyano may be introduced into these derivative compounds. For example, examples of a fluorescent material including tris-(8-hydroyquinolato)aluminum (III) (Alq₃) or a phosphorescent material may include fac tris(2-phenylpyridine)iridium (Ir(ppy)₃), bis(2-phenylpyridine) (acetylacetonate)iridium (III) (Ir(ppy)₂(acac)), tris[2-(p-tolyl)pyridine]iridium (III) (Ir(mppy)₃), and/or the like.

The plurality of stacks ST1, ST2, ST3, ST4, and ST5 may include hole transport layers HTL1, HTL2, HTL3, HTL4, and HTL5, respectively. The hole transport layers HTL1, HTL2, HTL3, HTL4, and HTL5 may be positioned on the anode electrode ANO or the charge generation layers CGL1, CGL2, CGL3, and CGL4. The hole transport layers HTL1, HTL2, HTL3, HTL4, and HTL5 may serve to facilitate the transport of holes and may each include a hole transport material. The hole transport material may include carbazole-based derivatives such as N-phenylcarbazole and poly(n-vinylcarbazole) (PVK), fluorene-based derivatives, triphenylamine-based derivatives such as N,N′-bis(3-methylphenyl)-N,N′-diphenyl-[1,1-biphenyl]-4,4′-diamine (TPD) or 4,4′,4″-tris(N-carbazolyl)triphenylamine (TCTA), N,N′-di(1-naphthyl)-N,N′-diphenylbenzidine (NPB), 4.4′-cyclohexylidene bis[N,N-bis(4-methylphenyl)benzenamine] (TAPC), and/or the like, but the present disclosure is not limited thereto.

The plurality of stacks ST1, ST2, ST3, ST4, and ST5 may include the above-described light emitting material layers EML1, EML2, EML3, EML4, and EML5 positioned on the hole transport layers HTL1, HTL2, HTL3, HTL4, and HTL5, respectively.

The plurality of stacks ST1, ST2, ST3, ST4, and ST5 may include electron transport layers ETL1, ETL2, ETL3, ETL4, and ETL5 positioned on the light emitting material layers EML1, EML2, EML3, EML4, and EML5, respectively. In one or more embodiments, each of the electron transport layers ETL1, ETL2, ETL3, ETL4, and ETL5 may include an electron transport material such as tris(8-hydroxyquinolinato)aluminum (Alq₃), 1,3,5-tri (1-phenyl-1H-benzo[d]imidazol-2-yl)phenyl (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq2), 9,10-di(naphthalen-2-yl) anthracene (ADN), and mixtures thereof. However, the present disclosure is not limited to the type or kind of the electron transport material described above.

The stack emitting the blue light may further include an electron blocking layer and a hole blocking layer. In one or more embodiments, the second stack ST2 and the third stack ST3 may include electron blocking layers EBL2 and EBL3 and hole blocking layers HBL2 and HBL3, respectively.

The electron blocking layers EBL2 and EBL3 may be arranged between the light emitting material layers EML2 and EML3 and the hole transport layers HTL2 and HTL3, respectively. The electron blocking layers EBL2 and EBL3 may include the above-described hole transport material or the above-described hole transport material and a metal (or a metal compound) so as to prevent or reduce electrons that have passed through the light emitting material layers EML2 and EML3 from passing to the hole transport layers HTL2 and HTL3. In one or more embodiments, each of the above-described hole transport layers HTL2 and HTL3 and electron blocking layers EBL2 and EBL3 may be formed as a single layer in which respective materials are blended with each other.

The hole blocking layers HBL2 and HBL3 may be arranged between the light emitting material layers EML2 and EML3 and the electron transport layers ETL2 and ETL3, respectively. The hole blocking layers HBL2 and HBL3 may include the above-described electron transport material or the above-described electron transport material and a metal (or a metal compound) so as to prevent or reduce holes that have passed through the light emitting material layers EML2 and EML3 from passing to the electron transport layers ETL2 and ETL3. In one or more embodiments, each of the above-described electron transport layers ETL2 and ETL3 and hole blocking layers HBL2 and HBL3 may be formed as a single layer in which respective materials are blended with each other.

The electron injection layer EIL may be arranged between the fifth stack ST5 and the cathode electrode CE and serve to facilitate the injection of electrons from the cathode electrode CE into the stacks ST1, ST2, ST3, ST4, and ST5. An electron injection material is a compound having the ability to transport electrons and having an excellent or suitable electron injection effect. For example, the electron injection material may be tris(8-hydroxyquinolino)aluminum (Alq₃), PBD, TAZ, spiro-PBD, BAlq, or SAIq, but the present disclosure is not limited thereto. In addition, the electron injection layer EIL may include a metal halide compound, for example, one or more selected from among the group including (e.g., consisting of) MgF₂, LiF, NaF, KF, RbF, CsF, FrF, LiI, NaI, KI, RbI, CsI, FrI, and CaF₂, but the present disclosure is not limited thereto. In addition, the electron injection layer EIL may include a lanthanum-based material such as Yb, Sm, or Eu. In one or more embodiments, the electron injection layer EIL may include both (e.g., simultaneously) a metal halide material and a lanthanum-based material such as RbI:Yb or KI:Yb. When the electron injection layer EIL includes both (e.g., simultaneously) the metal halide material and the lanthanum-based material, the electron injection layer EIL may be formed by co-deposition of the metal halide material and the lanthanum-based material.

Even though some of the plurality of stacks emit the same type or kind of component light, a method in which the plurality of stacks include the same material in the organic material layers and resonance distances are adjusted through thicknesses of the organic material layers may be used in order to control the resonance areas. In one or more embodiments, some of the plurality of stacks that are configured to emit the same type or kind of component light may include at least some of the materials of the organic material layers as different materials.

The charge generation layers CGL1, CGL2, CGL3, and CGL4 may be arranged between the plurality of stacks ST1, ST2, ST3, ST4, and ST5. The charge generation layers CGL1, CGL2, CGL3, and CGL4 may inject charges into the respective stacks ST1, ST2, ST3, ST4, and ST5 and adjust a charge balance between two adjacent stacks. The first charge generation layer CGL1 may be arranged between the first stack ST1 and the second stack ST2, the second charge generation layer CGL2 may be arranged between the second stack ST2 and the third stack ST3, the third charge generation layer CGL3 may be arranged between the third stack ST3 and the fourth stack ST4, and the fourth charge generation layer CGL4 may be arranged between the fourth stack ST4 and the fifth stack ST5. The charge generation layers CGL1, CGL2, CGL3, and CGL4 may include n-type or kind charge generation layers CGL11, CGL21, CGL31, and CGL41 and p-type or kind charge generation layers CGL12, CGL22, CGL32, and CGL42, respectively. The n-type or kind charge generation layers CGL11, CGL21, CGL31, and CGL41 may be arranged on the electron transport layer ETL1, ETL2, ETL3, and ETL4, respectively, and the p-type or kind charge generation layers CGL12, CGL22, CGL32, and CGL42 may be arranged between the n-type or kind charge generation layers CGL11, CGL21, CGL31, and CGL41 and the hole transport layers HTL2, HTL3, HTL4, and HTL5, respectively.

The charge generation layers CGL1, CGL2, CGL3, and CGL4 may have structures in which the n-type or kind charge generation layers CGL11, CGL21, CGL31, and CGL41 and the p-type or kind charge generation layers CGL12, CGL22, CGL32, and CGL42 are bonded to each other, respectively. The n-type or kind charge generation layers CGL11, CGL21, CGL31, and CGL41 are arranged more adjacent to the anode electrode ANO of the anode electrode ANO and the cathode electrode CE. The p-type or kind charge generation layers CGL12, CGL22, CGL32, and CGL42 are arranged more adjacent to the cathode electrode CE of the anode electrode ANO and the cathode electrode CE.

The stacks emitting the same type or kind of component light may have the same thickness or different thicknesses. In one or more embodiments, some of the plurality of stacks configured to emit the first component light LE1 may have different thicknesses from each other. In one or more embodiments, some of the plurality of stacks configured to emit the second component light LE2 may have different thicknesses from each other. The second stack ST2 and the third stack ST3 that are configured to emit the blue light may have different thicknesses. Two of (e.g., selected from among) the first stack ST1, the fourth stack ST4, and the fifth stack ST5 that are configured to emit the green yellow light may have different thicknesses from each other or all of (e.g., selected from among) the first stack ST1, the fourth stack ST4, and the fifth stack ST5 may have different thicknesses from each other. In one or more embodiments, the sum of the thicknesses of the stacks configured to emit the first component light LE1 and the sum of the thicknesses of the stacks configured to emit the second component light LE2 may be different from each other. In one or more embodiments, the hole transport layers HTL1, HTL2, HTL3, HTL4, and HTL5 of (e.g., selected from among) the first to fifth stacks ST1, ST2, ST3, ST4, and ST5 may have different thicknesses from each other.

Each stack may have a vertical distance from the hole transport layer to the electron transport layer as a thickness.

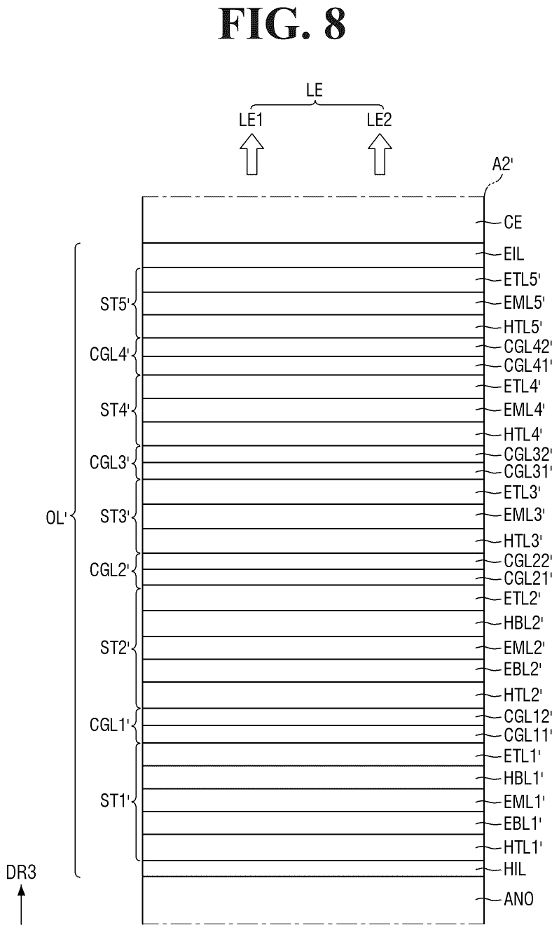

The present disclosure is not limited to the structure of FIG. 7, and a configuration and a structure of the organic material layer of the light emitting element may be changed so that the resonance areas of the first component light LE1 and the second component light LE2 overlap each other. FIG. 8 is an enlarged cross-sectional view of a light emitting element of a display device according to one or more embodiments.

FIG. 8 is different from FIG. 7 in a configuration of stacks. FIG. 8 is the same as in FIG. 7 in that some of (e.g., selected from among) the stacks are configured to emit the first component light LE1 and the others of (e.g., selected from among) the stacks are configured to emit the second component light LE2.

A first light emitting material layer EML1′ of a first stack ST1′ and a second light emitting material layer EML2′ of a second stack ST2′ may be configured to emit the first component light LE1, for example, blue light. A third light emitting material layer EML3′ of a third stack ST3′, a fourth light emitting material layer EML4′ of a fourth stack ST4′, and a fifth light emitting material layer EML5′ of a fifth stack ST5′ may be configured to emit the second component light LE2, for example, yellow light, green yellow light, or green light.

The first stack ST1′ and the second stack ST2′ that are configured to emit the blue light may include hole transport layers HTL1′ and HTL2′, electron blocking layers EBL1′ and EBL2′, light emitting material layers EML1′ and EML2′, hole blocking layers HBL1′ and HBL2′, and electron transport layers ETL1′ and ETL2′ that are sequentially stacked, respectively. The third stack ST3′, the fourth stack ST4′, and the fifth stack ST5′ that are configured to emit the yellow light, the green yellow light, or the green light may include hole transport layers HTL3′, HTL4′, and HTL5′, light emitting material layers EML3′, EML4′, and EML5′, and electron transport layers ETL3′, ETL4′, and ETL5′ that are sequentially stacked, respectively.

The light emitting material layers of two adjacent stacks of the plurality of stacks ST1′, ST2′, ST3′, ST4′, and ST5′ may be configured to emit the same type or kind of component light. For example, the first light emitting material layer EML1′ of the first stack ST1′ and the second light emitting material layer EML2′ of the second stack ST2′ may be configured to emit the first component light LE1. In one or more embodiments, the third light emitting material layer EML3′ of the third stack ST3′ and the fourth light emitting material layer EML4′ of the fourth stack ST4′ may be configured to emit the second component light LE2. The present disclosure is not limited thereto, and the two adjacent stacks may be configured to emit the same component light.

In one or more embodiments, some of the plurality of stacks configured to emit the first component light LE1 may have different thicknesses from each other. In one or more embodiments, some of the plurality of stacks configured to emit the second component light LE2 may have different thicknesses from each other. The first stack ST1′ and the second stack ST2′ that are configured to emit the blue light may have different thicknesses from each other. Two of the third stack ST3′, the fourth stack ST4′, and the fifth stack ST5′ that are configured to emit the green yellow light or the green light may have different thicknesses from each other or all of the third stack ST3′, the fourth stack ST4′, and the fifth stack ST5′ may have different thicknesses from each other. In one or more embodiments, the sum of the thicknesses of the stacks configured to emit the first component light LE1 and the sum of the thicknesses of the stacks configured to emit the second component light LE2 may be different from each other. In one or more embodiments, the hole transport layers HTL1′, HTL2′, HTL3′, HTL4′, and HTL5′ of (e.g., selected from among) the first to fifth stacks ST1′, ST2′, ST3′, ST4′, and ST5′ may have different thicknesses from each other.

As a material of an organic material layer applied to the light emitting layer OL′ of FIG. 8, the same material as that described in FIG. 7 may be used.

Referring to FIG. 5 again, the first capping layer CPL1 may be arranged on the cathode electrode CE. The first capping layer CPL1 may serve to improve viewing angle characteristics and increase external light emission efficiency. The first capping layer CPL1 may be commonly arranged in the first emission area EA1, the second emission area EA2, the third emission area EA3, and the non-emission area NEA. The first capping layer CPL1 may completely cover the cathode electrode CE.

The first capping layer CPL1 may include at least one of an inorganic material or an organic material having light transmitting properties. For example, the first capping layer CPL1 may be formed as an inorganic layer, formed as an organic layer, or formed as an organic layer including inorganic particles. In one or more embodiments, the first capping layer CPL1 may include triamine derivatives, carbazole biphenyl derivatives, arylenediamine derivatives, an aluminum chelate compound (Alq₃), and/or the like, but is limited thereto.

The thin film encapsulation layer TFE of the light emitting unit 100 may be arranged on the first capping layer CPL1. The thin film encapsulation layer TFE may serve to protect components positioned below the thin film encapsulation layer from external foreign substances such as moisture. The thin film encapsulation layer is commonly arranged in the first emission area EA1, the second emission area EA2, the third emission area EA3, and the non-emission area NEA. The thin film encapsulation layer may completely cover the first capping layer CPL1.

The thin film encapsulation layer TFE may include a lower inorganic encapsulation layer TFEa, an organic encapsulation layer TFEb, and an upper inorganic encapsulation layer TFEc that are sequentially stacked on the first capping layer CPL1.

The lower inorganic encapsulation layer TFEa may cover the first light emitting element, the second light emitting element, and the third light emitting element by completely covering the first capping layer CPL1 in the display area DA. The organic encapsulation layer TFEb may be arranged on the lower inorganic encapsulation layer TFEa to completely cover the lower inorganic encapsulation layer TFEa. The upper inorganic encapsulation layer TFEc may be arranged on the organic encapsulation layer TFEb to completely cover the organic encapsulation layer TFEb.

In one or more embodiments, each of the lower inorganic encapsulation layer TFEa and the upper inorganic encapsulation layer TFEc may be made of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride (SiON), lithium fluoride, and/or the like, but the present disclosure is not limited thereto.

In one or more embodiments, the organic encapsulation layer TFEb may be made of an acrylic resin, a methacrylic resin, polyisoprene, a vinyl-based resin, an epoxy-based resin, a urethane-based resin, a cellulose-based resin, a perylene-based resin, and/or the like, but the present disclosure is not limited thereto.

Hereinafter, the light transmitting unit 300 will be described in more detail with reference to FIG. 5.

The light transmitting unit 300 may have a structure in which a second substrate 310, a color filter layer 320, a second capping layer CPL2, a light transmitting member, a bank pattern BK, and a third capping layer CPL3 are sequentially stacked on the other side in the third direction DR3 (e.g., the lower portion).

The second substrate 310 of the light transmitting unit 300 may serve as a base of the light transmitting unit 300. The second substrate 310 may be made of a material having light transmitting properties. The second substrate 310 may be a glass substrate or a plastic substrate. When the second substrate 310 is the plastic substrate, the second substrate 310 may have flexibility. In one or more embodiments, if (e.g., when) the second substrate 310 is the plastic substrate, the second substrate 310 may include polyimide, but the present disclosure is not limited thereto. As described above, the light emitting unit 100 and the light transmitting unit 300 face each other in the third direction DR3, and thus, the first substrate 110 of the light emitting unit 100 and the second substrate 310 of the light transmitting unit 300 may face each other in the third direction DR3.

The color filter layer 320 of the light transmitting unit 300 may be arranged on the other side of the second substrate 310 in the third direction DR3, that is, between the second substrate 310 and the light emitting unit 100. The color filter layer 320 may include a filtering pattern area and a light blocking pattern unit BM. The light blocking pattern unit BM may be around (e.g., surround) the filtering pattern area. The filtering pattern area of the color filter layer 320 may define the light transmitting areas TA1, TA2, and TA3 of the light transmitting unit 300, and the light blocking pattern unit BM may define the light blocking area BA of the light transmitting unit 300.

The color filter layer 320 may include a first color filter 321, a second color filter 322, and a third color filter 323, as illustrated in FIG. 5. The first color filter 321 may be configured to absorb (substantially) all of the second light and (substantially) all of the third light except for the first light (e.g., not absorb the first light or (substantially) any of the first light), the second color filter 322 may be configured to absorb (substantially) all of the first light and (substantially) all of the third light except for the second light (e.g., not absorb the second light or (substantially) any of the second light), and the third color filter 323 may be configured to absorb (substantially) all of the first light and (substantially) all of the second light except for the third light (e.g., not absorb the third light or (substantially) any of the third light). For example, the first color filter 321 may be configured to transmit the first light therethrough, the second color filter 322 may be configured to transmit the second light therethrough, and the third color filter 323 may be configured to transmit the third light therethrough.

In one or more embodiments, the first color filter 321 may be a blue color filter, and may include blue colorants. In the present specification, a colorant is a concept including both (e.g., simultaneously) a dye and a pigment. The first color filter 321 may include a base resin, and the blue colorants may be dispersed in the base resin. In one or more embodiments, the second color filter 322 may be a green color filter, and may include green colorants. The second color filter 322 may include a base resin, and the green colorants may be dispersed in the base resin. In one or more embodiments, the third color filter 323 may be a red color filter, and may include red colorants. The third color filter 323 may include a base resin, and the red colorants may be dispersed in the base resin.

The first color filter 321 may include a first filtering pattern area 321a and a first light blocking pattern area 321b around (e.g., surrounding) the first filtering pattern area 321a, the second color filter 322 may include a second filtering pattern area 322a and a second light blocking pattern area 322b around (e.g., surrounding) the second filtering pattern area 322a, and the third color filter 323 may include a third filtering pattern area 323a and a third light blocking pattern area 323b around (e.g., surrounding) the third filtering pattern area 323a. For example, the first filtering pattern area 321a of the first color filter 321 may overlap the first light transmitting area TA1, and the first light blocking pattern area 321b of the first color filter 321 may be around (e.g., surround) the first filtering pattern area 321a overlapping the first light transmitting area TA1, but may not overlap the second light transmitting area TA2 and the third light transmitting area TA3, and may overlap the light blocking area BA. The second filtering pattern area 322a of the second color filter 322 may overlap the second light transmitting area TA2, and the second light blocking pattern area 322b of the second color filter 322 may be around (e.g., surround) the second filtering pattern area 322a overlapping the second light transmitting area TA2, but may not overlap the first light transmitting area TA1 and the third light transmitting area TA3, and may overlap the light blocking area BA. The third filtering pattern area 323a of the third color filter 323 may overlap the third light transmitting area TA3, and the third light blocking pattern area 323b of the third color filter 323 may be around (e.g., surround) the third filtering pattern area 323a overlapping the third light transmitting area TA3, but may not overlap the first light transmitting area TA1 and the second light transmitting area TA2, and may overlap the light blocking area BA. For example, the filtering pattern area of the color filter layer 320 may include the first filtering pattern area 321a of the first color filter 321, the second filtering pattern area 322a of the second color filter 322, and the third filtering pattern area 323a of the third color filter 323, and the light blocking pattern unit BM may have a structure in which the first light blocking pattern area 321b of the first color filter 321, the second light blocking pattern area 322b of the second color filter 322, and the third light blocking pattern area 323b of the third color filter 323 are stacked.

The first filtering pattern area 321a of the first color filter 321 may function as a blocking filter blocking the red light and the green light. For example, the first filtering pattern area 321a may selectively transmit the first light (e.g., the blue light) therethrough and block or absorb the second light (e.g., the green light) and the third light (e.g., the red light).

The second filtering pattern area 322a of the second color filter 322 may function as a blocking filter blocking the blue light and the red light. For example, the second filtering pattern area 322a may selectively transmit the second light (e.g., the green light) therethrough and block or absorb the first light (e.g., the blue light) and the third light (e.g., the red light).

The third filtering pattern area 323a of the third color filter 323 may function as a blocking filter blocking the blue light and the green light. For example, the third filtering pattern area 323a may selectively transmit the third light (e.g., the red light) therethrough and block or absorb the first light (e.g., the blue light) and the second light (e.g., the green light).

In one or more embodiments, the light blocking pattern unit BM may have a structure in which the first light blocking pattern area 321b, the third light blocking pattern area 323b, and the second light blocking pattern area 322b are sequentially stacked on the other side in the third direction DR3, but the present disclosure is not limited thereto. For example, the light blocking pattern unit BM may not be formed of the color filters 321, 322, and 323 described above, but may be formed through coating and exposing processes of a separate organic light blocking material. Hereinafter, for convenience of explanation, it will be mainly described that the light blocking pattern unit BM has the structure in which the first light blocking pattern area 321b, the third light blocking pattern area 323b, and the second light blocking pattern area 322b are sequentially stacked on the other side in the third direction DR3. The light blocking pattern unit BM may be configured to absorb all of the first light, all of the second light, and all of the third light through the above-described configuration.

A low refraction layer LR may be arranged on the color filter layer 320. The low refraction layer LR may serve to recycle light by having a low refractive index than a light transmitting layer TPL, a first wavelength conversion layer WCL1, and a second wavelength conversion layer WCL2 to be described in more detail later to induce total reflection of light traveling from the light transmitting layer TPL, the first wavelength conversion layer WCL1, and the second wavelength conversion layer WCL2 to the low refraction layer LR.

In addition, the low refraction layer LR may serve to compensate for and planarize a step (e.g., act or task) caused by the light blocking pattern areas 321b, 322b, and 323b of the color filter layer 320. Accordingly, the second capping layer CPL2 arranged on the low refraction layer LR may be formed to be flat. A thickness of the low refraction layer LR in the light blocking area BA and a thickness of the low refraction layer LR in the light transmitting areas TA1, TA2, and TA3 may be different from each other, and the thickness of the low refraction layer LR in the light blocking area BA may be smaller than the thickness of the low refraction layer LR in the light transmitting areas TA1, TA2, and TA3.

The second capping layer CPL2 of the light transmitting unit 300 may be arranged on one surface of the low refraction layer LR to cover the low refraction layer LR. The second capping layer CPL2 may prevent or reduce impurities such as moisture or air from permeating from the outside into the low refraction layer LR or the color filter layer 320 to damage to or contaminate the low refraction layer LR and the light blocking pattern unit BM and the filtering pattern area of the color filter layer 320. The second capping layer CPL2 may include an inorganic material. The second capping layer CPL2 may be formed as a single layer or multiple layers.

A refractive index of the second capping layer CPL2 may be greater than a refractive index of the low refraction layer LR. In this case, total reflection may occur well on the low refraction layer LR, and light may be recycled.

The bank pattern BK of the light transmitting unit 300 may be arranged on the second capping layer CPL2 in FIG. 5 so as to form spaces accommodating a light transmitting member to be described in more detail later. The number of spaces accommodating the light transmitting member may be plural, and the respective spaces may be spaced and/or apart (e.g., spaced apart or separated) from each other. For example, the bank pattern BK may serve to partition the spaces where the light transmitting member is arranged. The bank pattern BK may be in direct contact with the second capping layer CPL2. The bank pattern BK may be around (e.g., surround) the light transmitting member in the plan view. The bank pattern BK may be arranged to overlap the non-emission area NEA of the light emitting unit 100 and the light blocking area BA of the light transmitting unit 300. The bank pattern BK may not overlap the emission areas EA1, EA2, and EA3 of the light emitting unit 100 and the light transmitting areas TA1, TA2, and TA3 of the light transmitting unit 300.

In one or more embodiments, the bank pattern BK may include an organic material that is photocurable or an organic material that is photocurable and includes a light blocking material, but the present disclosure is not limited thereto.

The light transmitting member of the light transmitting unit 300 may be arranged on the second capping layer CPL2 exposed by the spaces spaced and/or apart (e.g., spaced apart or separated) from each other by the bank pattern BK. The light transmitting member may include the light transmitting layer TPL overlapping the first light transmitting area TA1, the first wavelength conversion layer WCL1 overlapping the second light transmitting area TA2, and the second wavelength conversion layer WCL2 overlapping the third light transmitting area TA3. In one or more embodiments, the light transmitting layer TPL, the first wavelength conversion layer WCL1, and the second wavelength conversion layer WCL2 may be referred to as a wavelength conversion layer or a wavelength conversion material layer in the claims.

The light transmitting layer TPL may be arranged in the space partitioned by the bank pattern BK and may overlap the first emission area EA1 and the first light transmitting area TA1 in the third direction DR3. The light transmitting layer TPL may be in direct contact with the second capping layer CPL2 and the bank pattern BK.

The light transmitting layer TPL may be a light transmitting pattern transmitting incident light therethrough. For example, the emitted light LE provided from the first light emitting element is the blue light as described above, and may be transmitted through the light transmitting layer TPL and the first filtering pattern area 321a of the first color filter 321 and then emitted to the outside of the display device 1. For example, the first emitted light L1 transmitted from the first emission area EA1 through the first light transmitting area TA1 and then emitted to the outside may be the blue light.

The light transmitting layer TPL may include a base resin 330. The base resin 330 may be made of an organic material having high light transmissivity. In one or more embodiments, the base resin 330 may include an organic material such as epoxy-based resin, an acrylic resin, a silicone resin, a cardo-based resin, or an imide-based resin, but the present disclosure is not limited thereto.

When the light transmitting layer TPL includes light scatterers, the light may be scattered in a random direction regardless of an incident direction of the light transmitted through the first light transmitting area TA1. When a total content (e.g., amount) of the light scatterers included in the light transmitting layer TPL is high, a luminance ratio at the front side may be high, but light efficiency is reduced.

When the resonance areas of the first component light LE1 and the second component light LE2 overlap each other in the light emitting layer OL of the light emitting element, even though the light transmitting layer TPL includes a trace amount of light scatterers or does not include the light scatterers, the light may be scattered and side visibility may be improved. In addition, the white angle difference depending on the viewing angle may be small, and the light efficiency may be high. Accordingly, a display device in which the resonance areas of the first component light LE1 and the second component light LE2 overlap each other may have both (e.g., simultaneously) high light efficiency and high luminance. In one or more embodiments, the light transmitting layer TPL may not include (e.g., may exclude any of) the light scatterers, or may include the light scatterers in an amount of about 8.5 wt % or less or about 3 wt % or less based on a total weight of (100 wt % of) the light transmitting layer TPL.

The light transmitting layer TPL may have a refractive index that is the same as or similar to that of the second capping layer CPL2. In one or more embodiments, the refractive index of the light transmitting layer TPL may be greater than the refractive index of the low refraction layer LR. When the second capping layer CPL2 does not have light scatterers, the refractive index of the second capping layer CPL2 may be the same as a refractive index of the base resin 330.

The first wavelength conversion layer WCL1 may be arranged in the space partitioned by the bank pattern BK and may overlap the second emission area EA2 and the second light transmitting area TA2 in the third direction DR3. The first wavelength conversion layer WCL1 may be in direct contact with the second capping layer CPL2 and the bank pattern BK.

The first wavelength conversion layer WCL1 may be a wavelength conversion pattern converting or shifting a peak wavelength of incident light into light having another specific peak wavelength and emitting the light having another specific peak wavelength. For example, the emitted light LE provided from the second light emitting element is the white light as described above, and may be transmitted through the first wavelength conversion layer WCL1 and the second filtering pattern area 322a of the second color filter 322 to be converted into green light having a peak wavelength in the range of about 510 nm to about 550 nm, and then emitted to the outside of the display device 1. For example, the second emitted light L2 transmitted from the second emission area EA2 through the second light transmitting area TA2 and then emitted to the outside may be the green light.

The first wavelength conversion layer WCL1 may include a base resin 330, light scatterers 331 dispersedly arranged in the base resin 330, and first wavelength shifters 332 dispersedly arranged in the base resin 330.

The light scatterer 331 may have a refractive index different from that of the base resin 330, and may form an optical interface with the base resin 330. The light scatterer 331 may be a light scattering particle. The light scatterer 333 may scatter light in a random direction regardless of an incident direction of incident light without substantially converting a wavelength of the light transmitted through the second light transmitting area TA2.

The light scatterer 331 is a material scattering at least some of the transmitted light, and may include a metal oxide particle or an organic particle. In one or more embodiments, the light scatterer 331 may include titanium oxide (TiO₂), zirconium oxide (ZrO₂), aluminum oxide (Al₂O₃), indium oxide (In₂O₃), zinc oxide (ZnO), tin oxide (SnO₂), and/or the like as metal oxide, and may include an acrylic resin, a urethane-based resin, and/or the like, as the organic particle, but the present disclosure is not limited thereto.

The first wavelength shifter 332 may convert or shift the peak wavelength of the incident light to another specific peak wavelength. The first wavelength shifter 332 may convert the emitted light LE, which is the white light provided from the second light emitting element, into green light having a single peak wavelength in the range of about 510 nm to about 550 nm and emit the green light.

In one or more embodiments, the first wavelength shifter 332 may be a quantum dot, a quantum rod, or a phosphor, but the present disclosure is not limited thereto. Hereinafter, for convenience of explanation, it will be mainly described that the first wavelength shifter 332 is a quantum dot. The quantum dot may be a particulate matter emitting a specific color while electrons are transitioning from a conduction band to a valence band. The quantum dot may be a semiconductor nanocrystal material. The quantum dot may have a specific bandgap according to its composition and size to absorb light and then emit light having a unique wavelength. Examples of semiconductor nanocrystals of the quantum dot may include group IV nanocrystals, group II-VI compound nanocrystals, group III-V compound nanocrystals, group IV-VI nanocrystals, and/or one or more (e.g., any suitable) combinations thereof.

A group II-VI compound may be selected from the group consisting of a binary compound selected from the group consisting of CdSe, CdTe, ZnS, ZnSe, ZnTe, ZnO, HgS, HgSe, HgTe, MgSe, MgS, and mixtures (e.g., combinations) thereof; a ternary compound selected from the group consisting of InZnP, AgInS, CulnS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof.

A group III-V compound may be selected from the group consisting of a binary compound selected from the group consisting of GaN, GaP, GaAs, GaSb, AlN, AlP, AlAs, AlSb, InN, InP, InAs, InSb, and mixtures thereof; a ternary compound selected from the group consisting of GaNP, GaNAs, GaNSb, GaPAs, GaPSb, AlNP, AlNAs, AlNSb, AIPAs, AIPSb, InGaP, InNP, InAlP, InNAs, InNSb, InPAs, InPSb, GaAlNP, and mixtures thereof; and a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof.

The group IV-VI compound may be selected from the group consisting of a binary compound selected from the group consisting of SnS, SnSe, SnTe, PbS, PbSe, PbTe, and mixtures thereof; a ternary compound selected from the group consisting of SnSeS, SnSeTe, SnSTe, PbSeS, PbSeTe, PbSTe, SnPbS, SnPbSe, SnPbTe, and mixtures thereof; and a quaternary compound selected from the group consisting of SnPbSSe, SnPbSeTe, SnPbSTe, and mixtures thereof. The group IV element may be selected from the group consisting of Si, Ge, and mixtures thereof. The group IV compound may be a binary compound selected from the group consisting of SiC, SiGe, and mixtures thereof.

Here, the binary compound, the ternary compound, or the quaternary compound may exist in a particle at a substantially uniform concentration or substantially non-uniform concentration (e.g., may exist in the particle in a state of partially or substantially different concentration distributions). In addition, the quantum dot may have a core/shell structure in which one quantum dot surrounds another quantum dot. An interface between a core and a shell may have a concentration gradient in which a concentration of elements existing in the shell decreases toward the center.

In one or more embodiments, the quantum dot may have a core-shell structure including a core including the above-described nanocrystals and a shell around (e.g., surrounding) the core. The shell of the quantum dot may serve as a passivation layer for maintaining semiconductor characteristics by preventing or reducing chemical modification of the core and/or serve as a charging layer for imparting electrophoretic characteristics to the quantum dot. The shell may be a single layer or multiple layers. An interface between a core and a shell may have a concentration gradient in which a concentration of elements existing in the shell decreases toward the center. Examples of the shell of the quantum dot may include metal or non-metal oxide, a semiconductor compound, combinations thereof, and/or the like.

Examples of the metal or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄, but the present disclosure is not limited thereto.

In addition, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like, but the present disclosure is not limited thereto.

The light emitted by the first wavelength shifter 332 may have a full width of half maximum (FWHM) of an emission wavelength spectrum of about 45 nm or less, about 40 nm or less, or about 30 nm or less, and therefore, color purity and color reproducibility of colors displayed by the display device 1 may be further improved. In addition, the light emitted by the first wavelength shifter 332 may be emitted toward several directions regardless of an incident direction of the incident light. Therefore, side visibility of the second color displayed in the second light transmitting area TA2 may be improved.

Some of the emitted light LE provided from the second light emitting element may not be converted into the green light by the first wavelength shifter 332, and may be transmitted through the first wavelength conversion layer WCL1 and then emitted. Components whose wavelengths are not converted by the first wavelength conversion layer WCL1 and which are incident on the second filtering pattern area 322a of the second color filter 322 among the emitted light LE may be blocked by the second filtering pattern area 322a. In contrast, the green light converted by the first wavelength conversion layer WCL1 among the emitted light LE is transmitted through the second filtering pattern area 322a and then emitted to the outside. For example, the second emitted light L2 emitted to the outside of the display device 1 through the second light transmitting area TA2 may be the green light.

The second wavelength conversion layer WCL2 may be arranged in the space partitioned by the bank pattern BK and may overlap the third emission area EA3 and the third light transmitting area TA3 in the third direction DR3. The second wavelength conversion layer WCL2 may be in direct contact with the second capping layer CPL2 and the bank pattern BK.

The second wavelength conversion layer WCL2 may be a wavelength conversion pattern converting or shifting a peak wavelength of incident light into light having another specific peak wavelength and emitting the light having another specific peak wavelength. For example, the emitted light LE provided from the third light emitting element is the white light as described above, and may be transmitted through the second wavelength conversion layer WCL2 and the third filtering pattern area 323a of the third color filter 323 to be converted into red light having a peak wavelength in the range of about 610 nm to about 650 nm, and then emitted to the outside of the display device 1. For example, the third emitted light L3 transmitted from the third emission area EA3 through the third light transmitting area TA3 and then emitted to the outside may be the red light.

The second wavelength conversion layer WCL2 may include a base resin 330, light scatterers 331 dispersedly arranged in the base resin 330, and second wavelength shifters 333 dispersedly arranged in the base resin 330.

The second wavelength shifter 333 may convert or shift the peak wavelength of the incident light to another specific peak wavelength. The second wavelength shifter 333 may convert the emitted light LE, which is the white light provided from the third light emitting element, into red light having a single peak wavelength in the range of about 610 nm to about 650 nm and emit the red light. The second wavelength shifter 333 may convert not only the blue light but also the green light into the red light and emit the red light. In one or more embodiments, the second wavelength shifter 333 may be a quantum dot, a quantum rod, or a phosphor, but the present disclosure is not limited thereto. When the second wavelength shifter 333 is the quantum dot, the second wavelength shifter 333 has substantially the same configuration as the first wavelength shifter 332 if (e.g., when) the first wavelength shifter 332 is the quantum dot as described above, and a description thereof will thus not be provided.

Some of the emitted light LE provided from the third light emitting element may not be converted into the red light by the second wavelength shifter 333, and may be transmitted through the second wavelength conversion layer WCL2 and then emitted. Components whose wavelengths are not converted by the second wavelength conversion layer WCL2 and which are incident on the third filtering pattern area 323a of the third color filter 323 among the emitted light LE may be blocked by the third filtering pattern area 323a. In contrast, the red light converted by the second wavelength conversion layer WCL2 among the emitted light LE is transmitted through the third filtering pattern area 323a and then emitted to the outside. For example, the third emitted light L3 emitted to the outside of the display device 1 through the third light transmitting area TA3 may be the red light.

The third capping layer CPL3 of the light transmitting unit 300 may be arranged on the bank pattern BK, the light transmitting layer TPL, the first wavelength conversion layer WCL1, and the second wavelength conversion layer WCL2, and may serve to prevent or reduce impurities such as moisture or air from permeating from the outside to damage or contaminate the light transmitting layer TPL, the first wavelength conversion layer WCL1, and the second wavelength conversion layer WCL2. The third capping layer CPL3 may cover the light transmitting layer TPL, the first wavelength conversion layer WCL1, and the second wavelength conversion layer WCL2.

The filling unit 500 may be interposed between the light emitting unit 100 and the light transmitting unit 300 to fill the space between the light emitting unit 100 and the light transmitting unit 300, as described above. In one or more embodiments, the filling unit 500 may be in direct contact with the upper inorganic encapsulation layer TFEc of the thin film encapsulation layer of the light emitting unit 100 and the third capping layer CPL3 of the light transmitting unit 300, but the present disclosure is not limited thereto.

In one or more embodiments, the filling unit 500 may be made of a material having an extinction coefficient of substantially 0. The refractive index and the extinction coefficient are correlated to each other, and as the refractive index decreases, the extinction coefficient also decreases. In addition, if (e.g., when) the refractive index is about 1.7 or less, the extinction coefficient may substantially converge to 0. In one or more embodiments, the filling unit 500 may be made of a material having a refractive index of about 1.7 or less, and accordingly, may prevent, minimize, or reduce a phenomenon in which light provided from the self-light emitting elements is absorbed while being transmitted through the filling unit 500. In one or more embodiments, the filling unit 500 may be made of an organic material having a refractive index of about 1.4 to about 1.6.

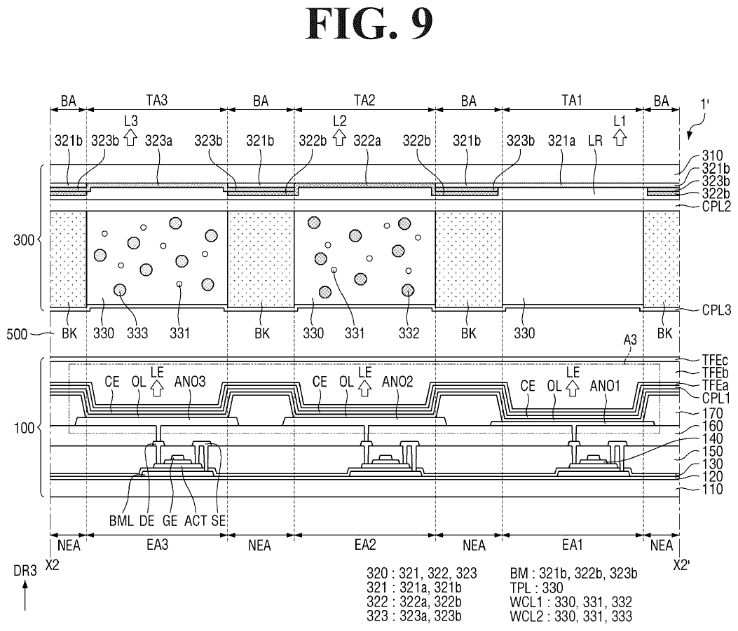

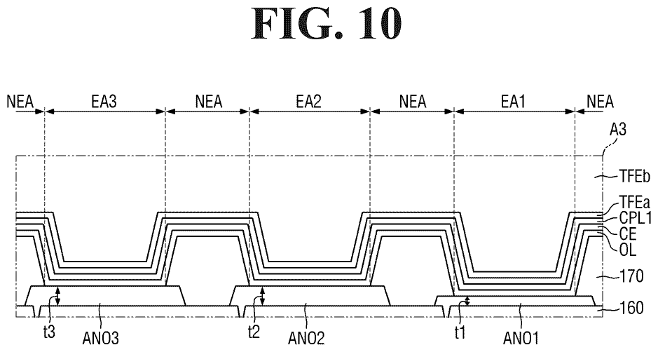

FIG. 9 is a cross-sectional view illustrating a portion of the display device according to one or more embodiments. FIG. 10 is an enlarged view of area A3 of FIG. 9.

As a method of adjusting resonance periods of different component lights LE1 and LE2 to overlap each other, there may be a method of making thicknesses of the anode electrodes ANO1, ANO2, and ANO3 different from each other in addition to a method of improving or optimizing the thickness of the organic material layer of the light emitting layer OL.

A first anode electrode ANO1 may be arranged on the first emission area EA1 of the third insulating layer 160, a second anode electrode ANO2 may be arranged on the second emission area EA2 of the third insulating layer 160, and a third anode electrode ANO3 may be arranged on the third emission area EA3 of the third insulating layer 160.

One of (e.g., selected from among) the first to third anode electrodes ANO1, ANO2, and ANO3 may have a different thickness from another one of (e.g., selected from among) the first to third anode electrodes ANO1, ANO2, and ANO3. In one or more embodiments, a thickness t1 of the first anode electrode ANO1 may be different from a thickness t2 of the second anode electrode ANO2 and a thickness t3 of the third anode electrode ANO3. The thickness t2 of the second anode electrode ANO2 may be the same as or different from the thickness t3 of the third anode electrode ANO3. The thickness t1 of the first anode electrode ANO1 may be smaller than the thickness t2 of the second anode electrode ANO2.

The resonance periods may be changed through the thicknesses of the anode electrodes so as to match characteristics desired or required for each of the emission area EA1, EA2, and EA3 and each of the light transmitting area TA1, TA2, and TA3.

The emitted light LE emitted from the light emitting elements in the first to third emission areas EA1, EA2, and EA3 may be white light. The emitted light LE may be a mixed light of the first component light LE1 and the second component light LE2. The first component light LE1 may be blue light, and the second component light LE2 may be yellow light, green yellow light, or green light. The light emitting layer OL may include a plurality of stacks sequentially stacked on the anode electrodes ANO1, ANO2, and ANO3, and the respective stacks may be configured to emit the component lights LE1 and LE2.

The first emitted light L1 emitted from the first emission area EA1 and passing through the first light transmitting area TA1 may be blue light, the second emitted light L2 emitted from the second emission area EA2 and passing through the second light transmitting area TA2 may be green light, and the third emitted light L3 emitted from the third emission area EA3 and passing through the third light transmitting area TA3 may be red light.

Configurations other than the anode electrodes ANO1, ANO2, and ANO3 may each independently be the same as those described in FIG. 5, and a description thereof will thus not be provided.

Hereinafter, a light emitting element of one or more embodiments of the present disclosure will be described in more detail.

### Manufacturing Example

A display device according to Example 1 was manufactured by manufacturing a light emitting element, a first capping layer CPL1, and a thin film encapsulation layer TFE that include materials as represented in Table 1 on a first substrate, manufacturing a light transmitting unit 300 on a second substrate, and bonding the light transmitting unit 300 and the thin film encapsulation layer TFE to each other with a filling unit 500. In this case, a light transmitting layer TPL of the light transmitting unit 300 does not include light scatterers 331. A cross section of the manufactured display device 10 may be as illustrated in FIG. 5.

TABLE 1

| | | |
|---|---|---|
| Layer | Material | Thickness (Å) |

| CPL1 | | | CPL | 500 |
|---|---|---|---|---|
| CE | | | Ag:Mg | 100(10%) |
| EIL | | | Yb | 10 |
| | ST5 | ETL5 | TPM-TAZ:Liq | 52(50%) |
| | | EML5 | GH:GYD | 20(7%) |
| | | HTL5 | TCTA | 36 |
| | CGL4 | CGL42 | TCPA:HATCN | 7(10%) |
| | | CGL41 | BCP:Li | 4(1%) |
| | ST4 | ETL4 | TPM-TAZ | 25 |
| | | EML4 | GH:GYD | 20(7%) |
| | | HTL4 | TCTA | 67 |
| | CGL3 | CGL32 | TCPA:HATCN | 7(10%) |
| | | CGL31 | BCP:Li | 4(1%) |
| | ST3 | ETL3 | TPM-TAZ | 25 |
| | | HBL3 | T2T | 5 |
| | | EML3 | BH:BD | 15(2%) |
| | | EBL3 | TCTA | 9 |
| | | HTL3 | TAPC | 57 |
| | CGL2 | CGL22 | TCPA:HATCN | 7(10%) |
| | | CGL21 | BCP:Li | 4(1%) |
| | ST2 | ETL2 | TPM-TAZ | 25 |
| | | HBL2 | T2T | 5 |
| | | EML2 | BH:BD | 15(2%) |
| | | EBL2 | TCTA | 9 |
| | | HTL2 | TAPC | 20 |
| | CGL1 | CGL12 | TCPA:HATCN | 7(10%) |
| | | CGL11 | BCP:Li | 4(1%) |
| | ST1 | ETL1 | TPM-TAZ | 25 |
| | | EML1 | GH:GYD | 20(7%) |
| | | HTL1 | TCTA | 51 |

| | | |
|---|---|---|
| HIL | TCPA:HATCN | 5(10%) |
| ANO | ITO/Ag/ITO | 80/800/80 |

Specific structures of the materials described in Table 1 are as follows.

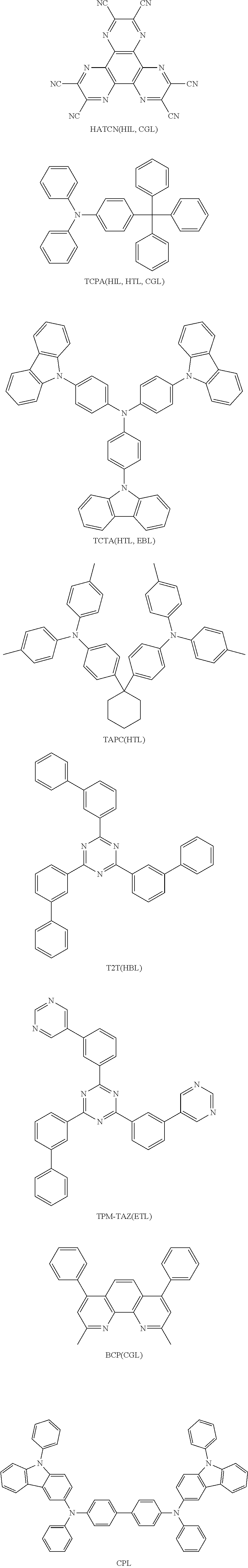

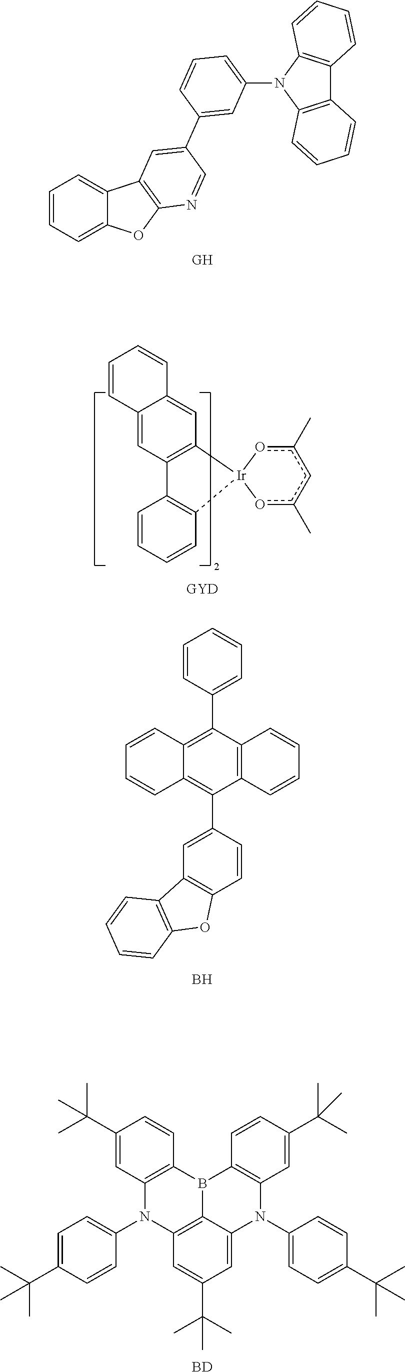

In Table 1, for each of layers including two or more types (kinds) of materials, a weight ratio of a dopant to a total weight of the corresponding layer was described in parentheses of the “thickness” column of the table. For example, a hole injection layer HIL included TCPA and HATCN, and HATCN was included as a dopant and was included in an amount of 10% based on the total weight of the hole injection layer HIL.

In one or more embodiments, a display device according to Comparative Example 1 was manufactured by continuously depositing three stacks configured to emit blue light on an anode electrode ANO and depositing one stack configured to emit green light on the last stack (BBBG). Materials of elements of Comparative Example 1 may be as represented in Table 2.

TABLE 2

| | | |
|---|---|---|
| Layer | Material | Thickness (Å) |

| CPL1 | | | CPL | 500 |
|---|---|---|---|---|
| CE | | | Ag:Mg | 100(10%) |
| EIL | | | Yb | 10 |
| | ST4_1 | ETL4_1 | TPM-TAZ:Liq | 52(50%) |
| | | EML4_1 | GH:GD | 28(7%) |
| | | HTL4_1 | TCTA | 30 |
| | CGL3_1 | CGL32_1 | TCPA:HATCN | 7(10%) |
| | | CGL31_1 | BCP:Li | 4(1%) |
| | ST3_1 | ETL3_1 | TPM-TAZ | 25 |
| | | HBL3_1 | T2T | 5 |
| | | EML3_1 | BH:BD | 15(2%) |
| | | EBL3_1 | TCTA | 5 |
| | | HTL3_1 | TAPC | 50 |
| | CGL2_1 | CGL22_1 | TCPA:HATCN | 7(10%) |
| | | CGL21_1 | BCP:Li | 4(1%) |
| | ST2_1 | ETL2_1 | TPM-TAZ | 25 |
| | | HBL2_1 | T2T | 5 |
| | | EML2_1 | BH:BD | 15(2%) |
| | | EBL2_1 | TCTA | 5 |
| | | HTL2_1 | TAPC | 60 |
| | CGL1_1 | CGL12_1 | TCPA:HATCN | 7(10%) |
| | | CGL11_1 | BCP:Li | 4(1%) |
| | ST1_1 | ETL1_1 | TPM-TAZ | 25 |
| | | HBL1_1 | T2T | 5 |
| | | EML1_1 | BH:BD | 15(2%) |
| | | EBL1_1 | TCTA | 5 |
| | | HTL1_1 | TAPC | 20 |

| | | |
|---|---|---|
| HIL | TCPA:HATCN | 5(10%) |
| ANO | ITO/Ag/ITO | 80/800/80 |

GD of the materials described in Table 2 is as follows, and the other materials are as represented in Table 1.

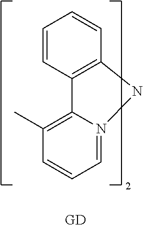

A display device according to Comparative Example 2 was manufactured in substantially the same manner as Comparative Example 1 except for the light scatterers 331 in the light transmitting layer TPL of the light transmitting unit 300 according to Comparative Example 1.

Structures of the display devices according to Comparative Example 1, Comparative Example 2, and Example 1 were compared with each other as represented in Table 3.

TABLE 3

| | Overlap between resonance | Light scatterer |
|---|---|---|
| | areas of first component light | 331 of light |
| | LE1 and second component | transmitting |
| | light LE2 | layer TPL |
| Comparative | X | ◯ (TiO₂) |
| Example 1 | | |
| Comparative | X | X |
| Example 2 | | |
| Example 1 | ◯ (light emitting layer in Table 1) | X |

### Evaluation Example 1 White Angular Difference (WAD) Comparison

WAD characteristics of the display devices according to Comparative Example 1, Comparative Example 2, and Example 1 were measured.

Color deviations (Δu′v′) according to a viewing angle were measured and represented in Table 4. u′v′ refers to a color coordinate value in the commission internationale de L'eclairage (CIE) u′v′ coordinate system, and the greater the color deviation (Δu′v′), the more likely it is to be viewed as a mura in user's eyes.

TABLE 4

| | Comparative | Comparative | |
|---|---|---|---|
| Angle (°) | Example 1 | Example 2 | Example 1 |
| −60 | 0.007 | 0.021 | 0.006 |
| −55 | 0.007 | 0.019 | 0.006 |
| −50 | 0.006 | 0.015 | 0.005 |
| −45 | 0.005 | 0.012 | 0.004 |
| −40 | 0.002 | 0.01 | 0.004 |
| −35 | 0.001 | 0.008 | 0.005 |
| −30 | 0 | 0.007 | 0.005 |
| −25 | 0.001 | 0.006 | 0.004 |
| −20 | 0.001 | 0.004 | 0.003 |
| −15 | 0.001 | 0.002 | 0.002 |
| −10 | 0 | 0.001 | 0.001 |
| −5 | 0 | 0 | 0 |
| 0 | 0 | 0 | 0 |
| 5 | 0 | 0 | 0 |
| 10 | 0 | 0.001 | 0.001 |
| 15 | 0.001 | 0.002 | 0.002 |
| 20 | 0.001 | 0.004 | 0.003 |
| 25 | 0.001 | 0.006 | 0.004 |
| 30 | 0 | 0.007 | 0.005 |
| 35 | 0.001 | 0.008 | 0.005 |
| 40 | 0.002 | 0.01 | 0.004 |
| 45 | 0.005 | 0.012 | 0.004 |
| 50 | 0.006 | 0.015 | 0.005 |
| 55 | 0.007 | 0.019 | 0.006 |
| 60 | 0.007 | 0.021 | 0.006 |

Referring to Table 4, the light transmitting layer TPL according to Comparative Example 2 did not include the light scatterers 331, and WAD characteristics of Comparative Example 2 were significantly deteriorated compared to Comparative Example 1. It can be seen that Example 1 represents WAD characteristics equivalent to those of Comparative Example 1 including the light scatterers even though the light transmitting layer TPL of the light transmitting unit 300 does not include the light scatterers.

### Evaluation Example 2 Light Efficiency Comparison

CIEx and CIEy of red, green, and blue were measured using an IVL measurement device, and RGB efficiency and white efficiency were represented in Table 5.

TABLE 5

| | | | | | | | | | | WHITE | |
|---|---|---|---|---|---|---|---|---|---|---|---|
| | | | | | | | | | | (0.280, | |
| | RED | | | GREEN | | | BLUE | | | 0.277) | |
| | Rx | Ry | R_Eff | Gx | Gy | G_Eff | Bx | By | B_Eff | W_Eff | ΔEff |
| Comparative | 0.699 | 0.297 | 12.1 | 0.229 | 0.733 | 46.7 | 0.146 | 0.041 | 5.7 | 21.3 | 100% |
| Example | | | | | | | | | | | |
| 1 | | | | | | | | | | | |
| Comparative | 0.699 | 0.297 | 12.1 | 0.229 | 0.733 | 46.7 | 0.146 | 0.041 | 9.6 | 24.2 | 114% |
| Example | | | | | | | | | | | |
| 2 | | | | | | | | | | | |
| Example | 0.694 | 0.303 | 14.5 | 0.23 | 0.732 | 70.4 | 0.141 | 0.044 | 11.8 | 30.4 | 143% |
| 1 | | | | | | | | | | | |

Referring to Table 5, it can be seen that the display devices according to Comparative Example 2 and Example 1 in which the light transmitting layer TPL does not include the light scatterers 331 have high blue light efficiency. However, it can be seen that white light efficiency is much higher in Example 1 in which the resonance areas overlap each other than in Comparative Examples 1 and 2.

Accordingly, it can be seen that the display device 10 according to one or more embodiments of the present disclosure has a small white angle difference even if (e.g., when) the angle changes and has high light efficiency.

The display device, the electronic apparatus, the electronic equipment, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

The embodiments of the present disclosure have been described hereinabove with reference to the accompanying drawings, but it will be understood by one of ordinary skill in the art to which the present disclosure pertains that one or more suitable modifications and alterations may be made without departing from the technical spirit or essential aspect of the present disclosure. Therefore, it is to be understood that one or more embodiments described above are illustrative rather than being restrictive in all aspects.

What is claimed is:

1. A display device comprising:
a first substrate comprising a first emission area and a second emission area spaced from each other;
a first light emitting element on the first substrate and overlapping the first emission area and a second light emitting element on the first substrate and overlapping the second emission area;
a light transmitting layer on the first light emitting element; and
a first wavelength conversion layer on the second light emitting element and comprising a light scatterer,
wherein each of the first light emitting element and the second light emitting element comprises four or more stacks,
wherein at least two selected from among the stacks are configured to emit first component light,
wherein at least two selected from among the stacks are configured to emit second component light, and
wherein any two adjacent stacks selected from among the stacks are configured to emit the first component light, and other two adjacent stacks selected from among the stacks are configured to emit the second component light.

2. The display device of claim 1, wherein the light transmitting layer does not comprise the light scatterer or comprises the light scatterer in an amount of about 8.5 wt % or less based on a total weight of the light transmitting layer.

3. The display device of claim 1, wherein the first component light is blue light, and the second component light is green yellow light, and
the first light emitting element and the second light emitting element are configured to emit white light.

4. The display device of claim 1, wherein resonance areas of the first component light and the second component light overlap each other.

5. The display device of claim 1, wherein each of the first light emitting element and the second light emitting element comprises an anode electrode, a hole injection layer on the anode electrode, a first stack on the hole injection layer, a second stack on the first stack, a third stack on the second stack, a fourth stack on the third stack, a fifth stack on the fourth stack, an electron injection layer on the fifth stack, and a cathode electrode on the electron injection layer, and
two stacks selected from among the first to fifth stacks are configured to emit the first component light, and the other three stacks selected from among the first to fifth stacks are configured to emit the second component light.

6. The display device of claim 5, wherein the two stacks configured to emit the first component light comprise different thicknesses from each other, and
two of the three stacks configured to emit the second component light comprise different thicknesses from each other.

7. The display device of claim 5, wherein a sum of the thicknesses selected from among the stacks configured to emit the first component light and a sum of the thicknesses selected from among the stacks configured to emit the second component light are different from each other.

8. The display device of claim 5, wherein the second stack and the third stack are configured to emit the first component light, and
the first stack, the fourth stack, and the fifth stack are configured to emit the second component light.

9. The display device of claim 5, wherein the first stack and the second stack are configured to emit the first component light, and
the third stack, the fourth stack, and the fifth stack are configured to emit the second component light.

10. The display device of claim 5, wherein the first to fifth stacks comprise first to fifth hole transport layers, respectively, and the first to fifth hole transport layers comprise different thicknesses from each other.

11. The display device of claim 5, wherein each of the first light emitting element and the second light emitting element comprises a first charge generation layer between the first stack and the second stack, a second charge generation layer between the second stack and the third stack, a third charge generation layer between the third stack and the fourth stack, and a fourth charge generation layer between the fourth stack and the fifth stack.

12. The display device of claim 1, wherein the first wavelength conversion layer further comprises a base resin and a first wavelength conversion shifter.

13. A display device comprising:
a first substrate comprising a first emission area and a second emission area spaced from each other;
a plurality of anode electrodes on the first substrate and in the first emission area and the second emission area;
a light emitting layer on the anode electrodes and comprising a plurality of stacks that are sequentially stacked;
a cathode electrode on the light emitting layer;
a light transmitting layer on the cathode electrode and overlapping the first emission area; and
a first wavelength conversion layer on the cathode electrode and overlapping the first emission area,
wherein a resonance area of first component light emitted by at least one selected from among the stacks and a resonance area of second component light emitted by at least another one selected from among the stacks overlap each other.

14. The display device of claim 13, wherein
the first component light is blue light,
the second component light is green yellow light, and
a fifth resonance area of the first component light and a fourth resonance area of the second component light overlap each other.

15. The display device of claim 13, wherein the light emitting layer comprises two or more stacks configured to emit the first component light and two or more stacks configured to emit the second component light.

16. The display device of claim 13, wherein the plurality of anode electrodes are reflective electrodes.

17. A display device comprising:
a first anode electrode and a second anode electrode spaced from each other on a first substrate;
a light emitting layer on the first anode electrode and the second anode electrode;
a cathode electrode on the light emitting layer;
a light transmitting layer on the cathode electrode and overlapping the first anode electrode; and
a first wavelength conversion layer on the cathode electrode and overlapping the second anode electrode,
wherein a thickness of the first anode electrode and a thickness of the second anode electrode are different from each other.

18. The display device of claim 17, wherein the thickness of the first anode electrode is smaller than the thickness of the second anode electrode.

19. The display device of claim 17, wherein the light emitting layer comprises a plurality of stacks, and
wherein a resonance area of first component light emitted by at least one selected from among the stacks and a resonance area of second component light emitted by at least another one selected from among the stacks overlap each other.

20. The display device of claim 19, wherein the first component light is blue light, and the second component light is green yellow light or green light.
